(19) United States
(12) Patent Application Publication
(10) Pub. No.: US 2026/0362867 A1
(43) Pub. Date: Nov. 12, 2026

(54) LIGHT-EMITTING DEVICE AND LIGHT-EMITTING MODULE

(71) Applicant: NICHIA CORPORATION, Anan-shi (JP)

(72) Inventors: Yuichi YAMADA, Itano-gun (JP); Seitaro AKAGAWA, Komatsushima-shi (JP); Tomonori OZAKI, Anan-shi (JP); Yasumasa YAMAMOTO, Myozai-gun (JP); Erina OKUNO, Itano-gun (JP)

(73) Assignee: NICHIA CORPORATION, Anan-shi (JP)

(21) Appl. No.: 19/642,940

(22) Filed: Apr. 9, 2026

(30) Foreign Application Priority Data
May 9, 2025 (JP) 2025-078448
Jul. 28, 2025 (JP) 2025-125471
Nov. 19, 2025 (JP) 2025-199055

(51) Int. Cl. H10H 20/857; H10H 20/85

(52) U.S. Cl. CPC H10H 20/857; H10H 20/8508

(57) ABSTRACT

A light-emitting device includes a support body, a light source part, a first conductive member, a second conductive member, and an insulating member. The support body includes a first surface, a second surface, a first through-hole, and a second through-hole. The light source part includes a first electrode and a second electrode. The first conductive member includes a first part, and a second part. The second conductive member includes a third part, and a fourth part. The insulating member overlaps a portion of the first part and a portion of the third part. The first conductive member includes a first region overlapping the insulating member, and a second region not overlapping the insulating member. A portion of the second region is positioned between portions of the first region.

### CROSS-REFERENCE TO RELATED APPLICATIONS

This application is based upon and claims the benefit of priority from Japanese Patent Application No. 2025-078448, filed on May 9, 2025, Japanese Patent Application No. 2025-125471, filed on Jul. 28, 2025, and Japanese Patent Application No. 2025-199055, filed on Nov. 19, 2025. The entire contents of these applications are incorporated herein by reference.

### BACKGROUND

Embodiments described herein relate generally to a light-emitting device and a light-emitting module.

JP-A 2017-188589 (Kokai) discloses a light-emitting device that includes a light-emitting element, a substrate having through-vias, and an insulating film covering a back surface of the substrate.

### SUMMARY

A light-emitting device includes a support body, a light source part, a first conductive member, a second conductive member and an insulating member. The support body includes a first surface, a second surface positioned at a side opposite to the first surface, a first through-hole, and a second through-hole. The light source part is positioned at the first surface side. The light source part includes a first electrode and a second electrode arranged in a first direction. The first conductive member is electrically connected to the first electrode. The first conductive member includes a first part positioned in the first through-hole, and a second part positioned at the second surface side. The second part is continuous with the first part. The second conductive member is electrically connected to the second electrode. The second conductive member includes a third part positioned in the second through-hole, and a fourth part positioned at the second surface side. The fourth part is continuous with the third part. The insulating member overlaps at least a portion of the first part and at least a portion of the third part when viewed from the second surface side. The first conductive member includes a first region overlapping the insulating member when viewed from the second surface side, and a second region not overlapping the insulating member when viewed from the second surface side.

At least a portion of the second region is positioned between portions of the first region in a second direction orthogonal to the first direction. The light-emitting device includes a wiring substrate including a first wiring part and a second wiring part, a first conductive body electrically connecting the first conductive member and the first wiring part, and a second conductive body electrically connecting the second conductive member and the second wiring part.

### BRIEF DESCRIPTION OF THE DRAWINGS

FIG. 1 is a schematic top view of a light-emitting device according to a first embodiment;

FIG. 2 is an enlarged view of region II of FIG. 1;

FIG. 3 is a schematic cross-sectional view of the light-emitting device along line III-III of FIG. 2;

FIG. 4 is a schematic cross-sectional view of a light source part according to the first embodiment;

FIG. 5 is a schematic bottom view showing a positional relationship of the light source part, a first conductive member, a second conductive member, and an insulating member of the light-emitting device according to the first embodiment;

FIG. 6 is a schematic cross-sectional view of the light-emitting device along line VI-VI of FIG. 5;

FIG. 7 is a schematic cross-sectional view of Modification 1 of the light-emitting device according to the first embodiment;

FIG. 8 is a schematic cross-sectional view of a light-emitting module according to a second embodiment;

FIG. 9 is a schematic bottom view showing a positional relationship of a base member, wiring parts, and a coating layer of the wiring substrate according to the second embodiment;

FIG. 10 is a schematic bottom view showing a positional relationship of the light source part, the first conductive member, the second conductive member, the insulating member, and the wiring substrate of the light-emitting module according to the second embodiment;

FIG. 11 is a schematic bottom view showing a positional relationship of the light source part, the first conductive member, the second conductive member, the insulating member, and the wiring substrate of Modification 1 of the light-emitting module according to the second embodiment;

FIG. 12 is a schematic bottom view showing a positional relationship of the light source part, the first conductive member, the second conductive member, the insulating member, and the wiring substrate of Modification 2 of the light-emitting module according to the second embodiment;

FIG. 13 is a schematic bottom view showing a positional relationship of the light source part, the first conductive member, the second conductive member, the insulating member, and the wiring substrate of Modification 3 of the light-emitting module according to the second embodiment;

FIG. 14 is a schematic bottom view showing a positional relationship of the light source part, the first conductive member, the second conductive member, the insulating member, and the wiring substrate of Modification 4 of the light-emitting module according to the second embodiment;

FIG. 15 is a schematic cross-sectional view of a light-emitting module according to a third embodiment;

FIG. 16 is a schematic cross-sectional view of a light-emitting device according to the third embodiment;

FIG. 17 is an enlarged view of region XVII of FIG. 16;

FIG. 18 is a schematic bottom view showing a positional relationship of the light source part, the first conductive member, the second conductive member, the insulating member, and the wiring substrate of the light-emitting module according to the third embodiment;

FIG. 19 is a schematic bottom view showing a positional relationship of the light source part, the first conductive member, the second conductive member, the insulating member, and the wiring substrate of Modification 1 of the light-emitting module according to the third embodiment;

FIG. 20 is a schematic cross-sectional view of Modification 1 of the light-emitting module according to the third embodiment;

FIG. 21 is a schematic bottom view showing a positional relationship of the light source part, the first conductive member, the second conductive member, the insulating member, and the wiring substrate of Modification 2 of the light-emitting module according to the third embodiment;

FIG. 22 is a schematic bottom view showing a positional relationship of the light source part, the first conductive member, the second conductive member, the insulating member, and the wiring substrate of Modification 3 of the light-emitting module according to the third embodiment;

FIG. 23 is a schematic cross-sectional view of a light-emitting device according to a fourth embodiment;

FIG. 24 is a schematic cross-sectional view of Modification 1 of the light-emitting device according to the fourth embodiment;

FIG. 25 is a schematic cross-sectional view of Modification 2 of the light-emitting device according to the fourth embodiment;

FIG. 26 is a schematic cross-sectional view of Modification 3 of the light-emitting device according to the fourth embodiment; and

FIG. 27 is a schematic cross-sectional view of Modification 4 of the light-emitting device according to the fourth embodiment.

### DETAILED DESCRIPTION

Exemplary embodiments will now be described with reference to the drawings. Because the drawings schematically show embodiments, the scales, spacing, positional relationships, and the like of the members may be exaggerated, or illustration of some of the members may be omitted. In the specification, the side of the arrow direction of the X-axis is referred to as the +X side, and the side opposite to the arrow direction of the X-axis is referred to as the -X side. The side of the arrow direction of the Y-axis is referred to as the +Y side, and the side opposite to the arrow direction of the Y-axis is referred to as the -Y side. The arrow direction of the Z-axis is referred to as up or above, and the side opposite to the arrow direction of the Z-axis is referred to as down or below. A view of an object from above may be referred to as a top view. A top view is synonymous with a plan view. A view of an object from below may be referred to as a bottom view. End views that show only cross sections may be used as cross-sectional views.

In the following description, components that have substantially the same function may be shown using common reference numerals, and a repeated description may be omitted. Terms that indicate specific directions or positions (e.g., "up,” "down,” and other terms including such terms) may be used. Such terms, however, are used merely for better understanding of relative directions or positions when referring to the drawings. As long as the relationships are the same, the relative directions or positions according to terms such as "up/above,” "down/below,” etc., used when referring to the drawings need not have the same arrangements in drawings, actual products, and the like outside the disclosure. In the specification, "parallel" includes not only the case where two straight lines, sides, surfaces, etc., do not cross even when extended, but also the case where the two straight lines, sides, surfaces, etc., cross at an angle within the range of 10°. The positional relationship referred to as "on" in the specification includes both the case of being in contact with another member and the case of being positioned above another member without being in contact with it.

### First embodiment

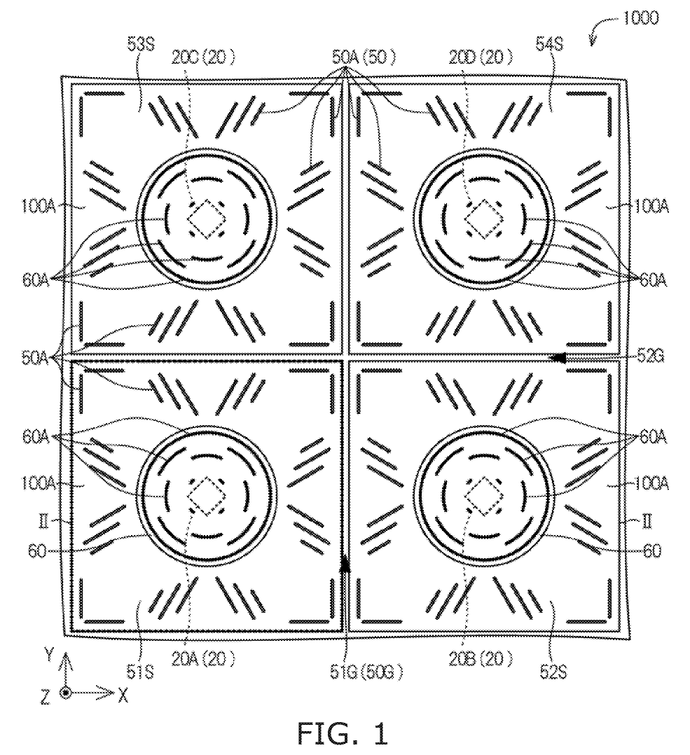

A light-emitting device 1000 of a first embodiment will now be described with reference to FIGS. 1-7. FIG. 1 is a drawing as viewed from the light-emitting surface side of the light-emitting device 1000. As shown in FIG. 1, two mutually orthogonal directions parallel to the light-emitting surface of the light-emitting device 1000 are taken as an X-direction and a Y-direction. A direction orthogonal to the X-direction and Y-direction is taken as a Z-direction. In the specification, the Z-direction may be referred to as the vertical direction.

The light-emitting device 1000 includes a support body 10, a light source part 20, conductive members 30, and an insulating member 40. The support body 10 includes a first surface 101, and a second surface 102 positioned at the side opposite to the first surface 101. The support body 10 includes a first through-hole 11H and a second through-hole 12H. The light source part 20 is positioned at the first surface 101 side of the support body 10. The light source part 20 includes a first electrode 21 and a second electrode 22. The first electrode 21 and the second electrode 22 are arranged in a first direction. The conductive members 30 include a first conductive member 31 and a second conductive member 32. The first conductive member 31 includes a first part 31A and a second part 31B. The first part 31A is positioned in the first through-hole 11H. The second part 31B is continuous with the first part 31A and is positioned at the second surface 102 side of the support body 10. The first conductive member 31 is electrically connected to the first electrode 21 of the light source part 20. The second conductive member 32 includes a third part 32A and a fourth part 32B. The third part 32A is positioned in the second through-hole 12H. The fourth part 32B is continuous with the third part 32A and is positioned at the second surface 102 side of the support body 10. The second conductive member 32 is electrically connected to the second electrode 22 of the light source part 20. The insulating member 40 overlaps at least a portion of the first part 31A when viewed from the second surface 102 side. The insulating member 40 overlaps at least a portion of the third part 32A when viewed from the second surface 102 side. The first conductive member 31 includes a first region 31R1 and a second region 31R2. The first region 31R1 of the first conductive member 31 overlaps the insulating member 40 when viewed from the second surface 102 side. The second region 31R2 of the first conductive member 31 does not overlap the insulating member 40 when viewed from the second surface 102 side. At least a portion of the second region 31R2 is positioned between portions of the first region 31R1 in a second direction which is orthogonal to the first direction.

According to the present embodiment, at least a portion of the second region 31R2 of the first conductive member 31 is positioned between portions of the first region 31R1 in the second direction. For the same shape of the insulating member, it is easier to increase the volume of the first conductive member 31 when at least a portion of the second region 31R2 of the first conductive member 31 is positioned between portions of the first region 31R1 in the second direction than when the second region 31R2 of the first conductive member 31 is not positioned between portions of the first region 31R1 in the second direction. With this structure, heat emitted by the light source part 20 can be transferred more easily to the first conductive member 31, which can inhibit a temperature rise of the light source part 20. This facilitates an increase in reliability of the light-emitting device 1000.

Components of the light-emitting device 1000 will now be described.

### Support body 10

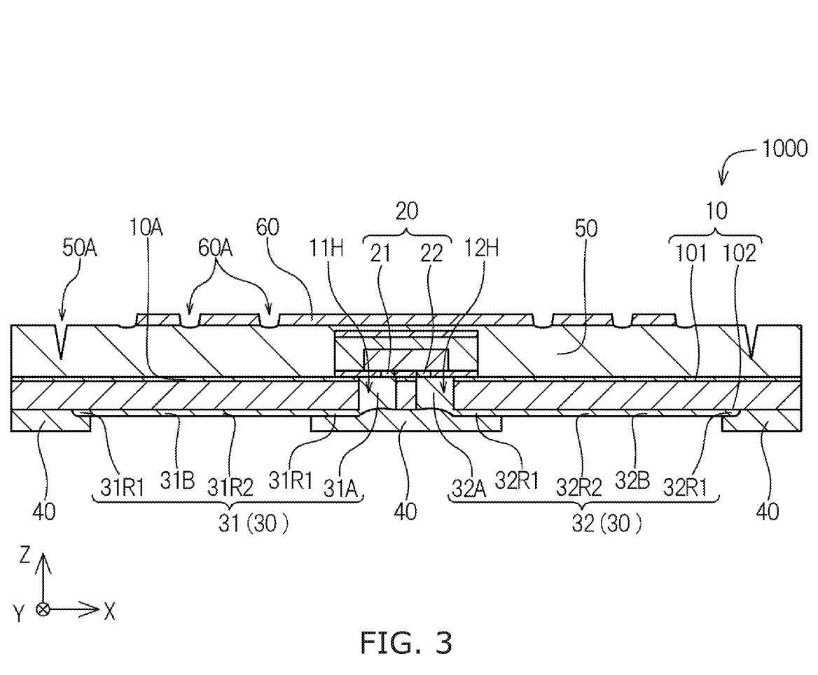

As shown in FIG. 3, the support body 10 is a member positioned below the light source part 20. According to the present embodiment, the light source part 20 is positioned on the support body 10 with a bonding layer 10A disposed therebetween. The support body 10 includes the first surface 101, and the second surface 102 positioned at the side opposite to the first surface 101. The support body 10 includes the first through-hole 11H and the second through-hole 12H. The first through-hole 11H is open at the first and second surfaces 101 and 102. The second through-hole 12H is open at the first and second surfaces 101 and 102. For example, a sheet-like optically clear adhesive (OCA) can be used as the material of the bonding layer 10A.

The material of the support body 10 is not particularly limited. For example, a resin or other insulating member can be used as the support body 10. Examples of the resin material of the support body 10 include thermoplastic resins such as an acrylic resin, a polycarbonate resin, a cyclic polyolefin resin, a polyethylene terephthalate resin, a polyester resin, etc., or a thermosetting resin such as an epoxy resin, a silicone resin, etc.

It is favorable for the support body 10 to be reflective to the light emitted by the light source part 20. The support body 10 being light-reflective makes it easier to increase the light extraction efficiency of the light-emitting device 1000. The support body 10 may include a resin member, and a reflector included in the resin member. Examples of the material of the reflector of the support body 10 include light-reflecting particles of titania, silica, alumina, zinc oxide, magnesium oxide, zirconia, yttria, calcium fluoride, magnesium fluoride, niobium pentoxide, barium titanate, tantalum pentoxide, barium sulfate, glass, etc.

A gas such as nitrogen, oxygen, etc., may be used as the reflector of the support body 10. The support body 10 may include both light-scattering particles and a gas as the reflector.

It is favorable for the support body 10 to be a resin member including a gas such as nitrogen, oxygen, etc.

Typically, the refractive index of the gas such as nitrogen, oxygen, etc., has a smaller refractive index than the resin member or the like that is the base material. Therefore, a portion of the light from the light source part 20 that is incident on the resin member is totally reflected more easily at the interface between the resin member and the gas. As a result, the light that travels downward from the light source part 20 is totally reflected more easily by the support body. As a result, it is easier to increase the light extraction efficiency of the light-emitting device 1000.

Although not particularly limited, it is favorable for the thickness of the support body 10 to be not less than 50 μm and not more than 600 μm. The thickness of the support body 10 being not less than 50 μm makes it easier to improve the reflectance of the support body 10. The thickness of the support body 10 being not more than 600 μm makes it easier to reduce the lengths of the first and second conductive members 31 and 32 in the vertical direction. As a result, when the light-emitting device 1000 is mounted to the wiring substrate, it is easier to reduce the path that conducts the heat emitted by the light source part 20 to the wiring substrate. As a result, a temperature rise of the light source part 20 can be inhibited. This facilitates an increase in reliability of the light-emitting device 1000. In the specification, unless defined otherwise, the thickness of a member is the maximum length of the member in the vertical direction. For example, the thickness of the support body 10 is the value when the length of the support body 10 in the vertical direction is a maximum.

It is favorable for the thickness of the support body 10 to be less than the maximum length of the first part 31A in the first direction. With this structure, it is easier to reduce the lengths of the first and second conductive members 31 and 32 in the vertical direction. As a result, when the light-emitting device 1000 is mounted to a wiring substrate, it is easier to reduce the conduction path to the wiring substrate of the heat emitted by the light source part 20. As a result, a temperature rise of the light source part 20 can be inhibited. Similarly, it is favorable for the thickness of the support body 10 to be less than the maximum length of the first part 31A in the second direction. It is also favorable for the thickness of the support body 10 to be less than the maximum length of the first part 31A in the first direction and the maximum length of the first part 31A in the second direction.

The bonding layer 10A may be reflective to the light emitted by the light source part 20. The bonding layer 10A being light-reflective makes it easier to increase the light extraction efficiency of the light-emitting device 1000. The bonding layer 10A can include a resin member, and a reflector included in the resin member. A material similar to the resin member of the support body 10 can be used as the material of the resin member of the bonding layer 10A. A material similar to the reflector of the support body 10 can be used as the material of the reflector of the bonding layer 10A. In some examples, the bonding layer 10A does not include a reflector.

In a cross-sectional view, it is favorable for the ratio of the area of the reflector of the bonding layer 10A to the area of the resin member of the bonding layer 10A to be less than the ratio of the area of the reflector of the support body 10 to the area of the resin member of the support body 10. As a result, it is easier to inhibit the reflector of the bonding layer 10A from shielding the light traveling upward after being totally reflected by the support body 10. As a result, it is easier to increase the light extraction efficiency of the light-emitting device 1000.

It is favorable for the refractive index of the resin member of the bonding layer 10A to be less than the refractive index of the resin member of a light-transmitting member 50, which is described below. As a result, it is easier for a portion of the light from the light source part 20 traveling from the light-transmitting member 50 to the bonding layer 10A to be totally reflected at the interface between the light-transmitting member 50 and the bonding layer 10A. As a result, the light that escapes below the light-emitting device 1000 can be reduced, making it easier to increase the light extraction efficiency of the light-emitting device 1000. In the specification, the refractive index refers to the refractive index of the light emission peak wavelength of the light source part 20.

### Light source part 20

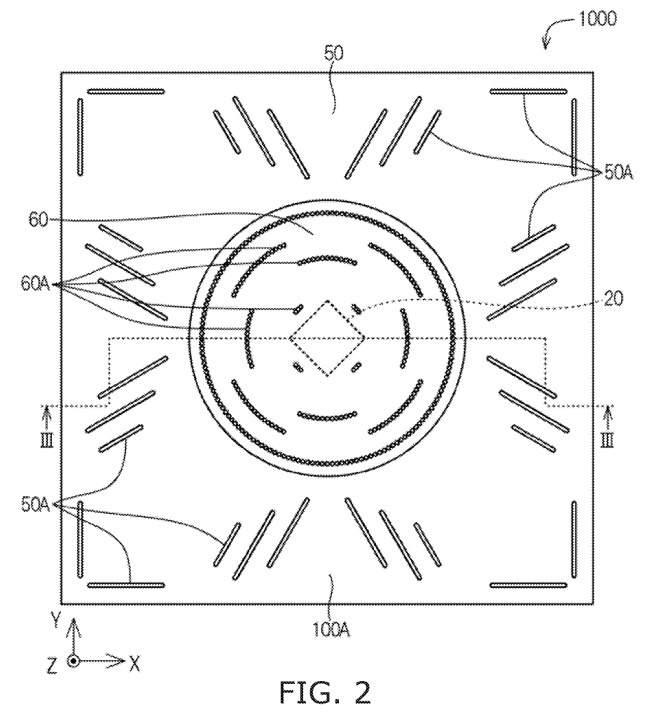

As shown in FIG. 1, the light-emitting device 1000 includes multiple light source parts 20 including a first light source 20A, a second light source 20B, a third light source 20C, and a fourth light source 20D. The number of the light source parts 20 included in the light-emitting device 1000 may be one. For example, as in FIG. 2, the light-emitting device may include one light source part 20. The light source part 20 is positioned closer to the first surface 101 side of the support body 10 than the second surface 102. The light source part 20 of the present embodiment is positioned on the first surface 101 of the support body 10.

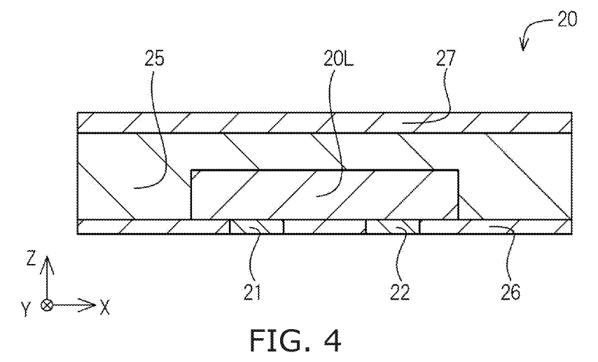

As shown in FIG. 4, the light source part 20 includes a light-emitting element 20L. The light-emitting element 20L includes a semiconductor stacked body. The semiconductor stacked body includes, for example, a substrate of sapphire, gallium nitride, or the like, an n-type semiconductor layer located on the substrate, a p-type semiconductor layer, and an active layer located between the n-type semiconductor layer and the p-type semiconductor layer. The active layer may have a single quantum well (SQW) structure, or may have a multi-quantum well (MQW) structure including multiple well layers. The semiconductor structure body includes multiple semiconductor layers made of a nitride semiconductor. The nitride semiconductor includes all compositions of semiconductors of the chemical formula InₓAl_{y}Ga_{1- x - y}N (0 ≤ x, 0 ≤ y, and x + y ≤ 1) for which the composition ratios x and y are changed within the ranges respectively. The light emission peak wavelength of the active layer can be appropriately selected according to the purpose. For example, the active layer is configured to emit visible light or ultraviolet light.

The semiconductor structure body may include multiple light-emitting parts including an n-side semiconductor layer, an active layer, and a p-side semiconductor layer. When the semiconductor structure body includes multiple light-emitting parts, the light-emitting parts may include well layers having different light emission peak wavelengths, or may include well layers having the same light emission peak wavelength. The light emission peak wavelength being the same also includes cases where there is fluctuation of about several nm. The combination of the light emission peak wavelengths of the multiple light-emitting parts can be selected as appropriate. For example, when the semiconductor structure body includes two light-emitting parts, examples of combinations of the light emitted by the light-emitting parts include combinations such as blue light and blue light, green light and green light, red light and red light, ultraviolet light and ultraviolet light, blue light and green light, blue light and red light, green light and red light, etc. For example, when the semiconductor structure body includes three light-emitting parts, examples of combinations of the light emitted by the light-emitting parts include a combination of blue light, green light, and red light. Each light-emitting part may include one or more well layers having different light emission peak wavelengths from the other well layers.

The light-emitting element 20L includes an n-side electrode electrically connected to the n-type semiconductor layer, and a p-side electrode electrically connected to the p-type semiconductor layer. The n-side electrode and the p-side electrode form portions of the lower surface of the light-emitting element 20L. The light source part 20 also includes an n-side metal post electrically connected to the n-side electrode, and a p-side metal post electrically connected to the p-side electrode. The first electrode 21 of the present embodiment includes both the p-side electrode and the p-side metal post. In some examples, the light source part 20 does not include the p-side metal post. When the light source part 20 does not include the p-side metal post, the first electrode 21 includes the p-side electrode. The second electrode 22 of the present embodiment includes both the n-side electrode and the n-side metal post. In some examples, the light source part 20 does not include the n-side metal post. When the light source part 20 does not include the n-side metal post, the second electrode 22 includes the n-side electrode. The p-side metal post and the n-side metal post include, for example, copper (Cu) and/or nickel (Ni). In some examples, the light source part 20 does not include a substrate of sapphire, gallium nitride, etc. As a result, it is easier to make the light source part 20 smaller in the vertical direction. According to the present embodiment, the first electrode 21 and the second electrode 22 are arranged in the first direction (the X-direction). In the specification, "a first member and a second member are arranged in the first direction" means that at least a portion of the first member and at least a portion of the second member are positioned on a straight line along the first direction. For example, "the first electrode 21 and the second electrode 22 are arranged in the first direction" means that at least a portion of the first electrode 21 and at least a portion of the second electrode 22 are positioned on a straight line along the first direction.

As shown in FIG. 4, the light source part 20 can further include a light-transmitting member (hereinbelow, referred to as a first light-source light-transmitting member 25). The first light-source light-transmitting member 25 covers the upper surface and side surface of the light-emitting element 20L. The light-emitting element 20L can be protected with the first light-source light-transmitting member 25. The first light-source light-transmitting member 25 may be arranged to expose at least a portion of the upper surface of the light-emitting element 20L. As a result, it is easier to make the light source part 20 smaller in the vertical direction.

For example, the first light-source light-transmitting member 25 is transmissive to the light emitted by the light-emitting element 20L. The first light-source light-transmitting member 25 includes a light-transmitting resin, and may further include a phosphor. For example, a silicone resin, an epoxy resin, etc., can be used as the light-transmitting resin. Examples of the phosphor include an yttrium-aluminum-garnet-based phosphor (e.g., (Y, Gd)₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂:Eu), an SAE-based phosphor (e.g., Sr₄Al₁₄O₂₅:Eu), a chlorosilicate-based phosphor (e.g., Ca₈MgSi₄O₁₆Cl₂:Eu), a silicate-based phosphor (e.g., (Ba, Sr, Ca, Mg)₂SiO₄:Eu), an oxynitride-based phosphor such as a β-sialon-based phosphor (e.g., (Si, Al)₃(O, N)₄:Eu), an α-sialon-based phosphor (e.g., Ca(Si, Al)₁₂(O, N)₁₆:Eu), or the like, a nitride-based phosphor such as an LSN-based phosphor (e.g., (La, Y)₃Si₆N₁₁:Ce), a BSESN-based phosphor (e.g., (Ba, Sr)₂Si₅N₈:Eu), an SLA-based phosphor (e.g., SrLiAl₃N₄:Eu), a CASN-based phosphor (e.g., CaAlSiN₃:Eu), a SCASN-based phosphor (e.g., (Sr, Ca)AlSiN₃:Eu), or the like, a fluoride-based phosphor such as a KSF-based phosphor (e.g., K₂SiF₆:Mn), a KSAF-based phosphor (e.g., K₂(Si₁-xAlx)F₆-x:Mn, in which x satisfies 0 < x < 1), a MGF-based phosphor (e.g., 3.5MgO⋅0.5MgF₂⋅GeO₂:Mn), or the like, a quantum dot having a perovskite structure (e.g., (Cs, FA, MA)(Pb, Sn)(F, Cl, Br, I)₃, in which FA and MA respectively represent formamidinium and methylammonium), a Group II-VI quantum dot (e.g., CdSe), a Group III-V quantum dot (e.g., InP), a quantum dot having a chalcopyrite structure (e.g., (Ag, Cu)(In, Ga)(S, Se)₂), etc. One type of phosphor or multiple types of phosphors may be used as the phosphor added to the first light-source light-transmitting member 25.

A wavelength conversion sheet that includes the phosphor described above may be located at the upper side of the light-emitting device 1000. The wavelength conversion sheet can be used as a planar light source that emits white light by absorbing a portion of the blue light from the light source part 20 and by emitting yellow light, green light, and/or red light. For example, white light can be obtained by combining the light source part 20 capable of a blue light emission and a wavelength conversion sheet including a phosphor capable of a yellow light emission. Also, the light source part 20 that is capable of a blue light emission may be combined with a wavelength conversion sheet that includes a red phosphor and a green phosphor. The light source part 20 that is capable of a blue light emission may be combined with multiple wavelength conversion sheets. For example, a wavelength conversion sheet that includes a phosphor capable of a red light emission and a wavelength conversion sheet that includes a phosphor capable of a green light emission can be selected as the multiple wavelength conversion sheets. The light source part 20 that includes the light-emitting element 20L capable of a blue light emission and the first light-source light-transmitting member 25 including a phosphor capable of a red light emission may be combined with a wavelength conversion sheet that includes a phosphor capable of a green light emission.

For example, it is favorable to use the yttrium-aluminum-garnet-based phosphor described above as the phosphor capable of a yellow light emission used in the wavelength conversion sheet. As the phosphor capable of a green light emission used in the wavelength conversion sheet, it is favorable to use a phosphor having a narrow width at half maximum of the light emission peak wavelength such as, for example, the quantum dot having the perovskite structure, the Group III-V quantum dot, or the quantum dot having the chalcopyrite structure described above. As the phosphor capable of a red light emission used in the wavelength conversion sheet, it is favorable to use a phosphor having a narrow width at half maximum of the light emission peak wavelength similarly to the phosphor capable of a green light emission such as, for example, the KSF-based phosphor, the KSAF-based phosphor, the Group III-V quantum dot, or the quantum dot having the chalcopyrite structure described above.

A band-pass filter that transmits light of a specific wavelength region and reflects light of other wavelength regions may be located between the wavelength conversion sheet and the light source part 20. For example, a dichroic sheet is used as the band-pass filter. It is favorable for the band-pass filter to transmit only blue light and reflect light of other colors (green light and red light). As a result, only blue light among the light from the light source part 20 can be incident on the wavelength conversion sheet, making it easy to emit white light from the wavelength conversion sheet by combining a wavelength conversion sheet that absorbs a portion of the blue light from the light source part 20 and emits white light. Also, light (e.g., green light, red light, etc.) other than blue light that is transmitted by the band-pass filter and reflected by the wavelength conversion sheet can be inhibited from returning to the light source part 20 side. As a result, uneven luminance of the light-emitting device 1000 is reduced.

A diffusion sheet may be located between the band-pass filter and the light source part 20. The diffusion sheet can transmit the light from the light source part 20 and diffuse the transmitted light when emitting the light from the diffusion sheet toward the band-pass filter side. As a result, uneven luminance of the light-emitting device 1000 can be reduced. It is favorable for the diffusion sheet to include a material having low absorptivity for the light emitted by the light-emitting element 20L. Examples of the diffusion sheet include polycarbonate, polystyrene, acrylic, polyethylene, etc.

The diffusion sheet may include a micro unevenness at the emission surface, and may include a light-diffusing optical film. The diffusion sheet may include a single layer, or may include a stacked body of multiple layers.

A prism sheet may be located at the upper side of the wavelength conversion sheet. Multiple prisms that extend in one direction are arranged in a surface of the prism sheet. The prism sheet may include one prism sheet or multiple overlaid prism sheets. When multiple overlaid prism sheets are used, for example, one of the multiple prism sheets may have prisms extending in the X-direction, and another one of the multiple prism sheets may have prisms extending in the Y-direction. As a result, the light that is emitted from the prism sheet can be aligned in a direction orthogonal to the emission surface of the prism sheet, and the luminance of the light-emitting device 1000 in a top view can be increased.

The light source part 20 can further include a covering member 26. The covering member 26 is reflective to the light emitted by the light-emitting element 20L. The covering member 26 is located at the lower surface side of the light-emitting element 20L. The covering member 26 is arranged so that the lower surface of the first electrode 21 and the lower surface of the second electrode 22 are exposed from under the covering member 26. The covering member 26 also is located at the lower surface of the first light-source light-transmitting member 25 covering the side surface of the light-emitting element 20L.

As shown in FIG. 4, the light source part 20 can include a light-modulating member (hereinbelow, referred to as a light-source light-modulating member 27). The light-source light-modulating member 27 forms at least a portion of the upper surface of the light source part 20. The light-source light-modulating member 27 is positioned at the upper side of the light-emitting element 20L. The light-source light-modulating member 27 and the light-emitting element 20L overlap in a top view, and the light-source light-modulating member 27 is positioned at the upper side of the light-emitting element 20L at the overlapping portion. The light-source light-modulating member 27 is positioned at the upper side of the first light-source light-transmitting member 25, and modulates the amount and/or emission direction of the light emitted from the upper surface of the first light-source light-transmitting member 25. The light-source light-modulating member 27 is reflective and transmissive to the light emitted by the light-emitting element 20L. A portion of the light emitted from the upper surface of the first light-source light-transmitting member 25 is reflected by the light-source light-modulating member 27, and another portion is transmitted by the light-source light-modulating member 27. The transmittance of the light-source light-modulating member 27 for the light emission peak wavelength of the light-emitting element 20L is, for example, favorably not less than 1% and not more than 50%, and more favorably not less than 3% and not more than 30%. By the light source part 20 including the light-source light-modulating member 27, the region directly above the light source part 20 can be inhibited from becoming excessively bright. As a result, it is easier to reduce uneven luminance of the light-emitting device 1000.

The light-source light-modulating member 27 can include, for example, a resin member, and a reflector included in the resin member. A material similar to the resin member of the support body 10 can be used as the material of the resin member of the light-source light-modulating member 27. A material similar to the reflector of the support body 10 can be used as the material of the reflector of the light-source light-modulating member 27. The light-source light-modulating member 27 may be, for example, a metal member such as aluminum, silver, or the like, or a dielectric multilayer film.

The light source part 20 may not include the light-source light-modulating member 27. That is, the upper surface of the light source part 20 may be formed of the upper surface of the light-emitting element 20L and/or the upper surface of the first light-source light-transmitting member 25. As a result, it is easier to make the light source part 20 smaller in the vertical direction than when the light source part 20 includes the light-source light-modulating member 27 positioned at the upper side of the light-emitting element 20L. As another configuration of the light source part 20, the light source part 20 may not include the covering member 26. That is, the lower surface of the light source part 20 may be formed of the lower surface of the light-emitting element 20L and the lower surface of the first light-source light-transmitting member 25. As another configuration of the light source part 20, the light source part 20 may be only a single light-emitting element 20L. As another configuration of the light source part 20, the light source part 20 may not include the first light-source light-transmitting member 25 and the covering member 26, and the light-source light-modulating member 27 may be positioned at the upper surface of the light-emitting element 20L. As another configuration of the light source part 20, the light source part 20 may not include the first light-source light-transmitting member 25, the light-source light-modulating member 27 may be positioned at the upper surface of the light-emitting element 20L, and the covering member 26 may be positioned at the lower surface of the light-emitting element 20L. The light source part 20 may include a mounting substrate, and a light-emitting element placed on the mounting substrate. When the mounting substrate includes a recess, the light-emitting element may be positioned in the recess.

The shape of the light source part 20 in a top view is not particularly limited. The shape of the light source part 20 in a top view can be, for example, circular, triangular, quadrilateral, hexagonal, octagonal, or another shape. When the shape of the light source part 20 in a top view is quadrilateral, a pair of outer edges of the light source part 20 may be parallel to the X-direction, or may be oblique to the X-direction. According to the present embodiment, a pair of outer edges of the light source part 20 is tilted 45° with respect to the X-direction.

### Conductive member 30

The conductive members 30 are conductive members that supply power to the light source part 20. The material of the conductive members 30 is not particularly limited. For example, a resin and a conductive paste including metal particles included in the resin can be used as the material of the conductive members 30. For example, an epoxy resin or a phenolic resin can be used as the resin of the conductive members 30. For example, copper or silver particles can be used as the metal particles of the conductive members 30.

The conductive members 30 may include a thermosetting resin, and the support body 10 may include a thermoplastic resin. In such a case, it is favorable for the melting point of the thermoplastic resin of the support body 10 to be greater than the curing temperature of the thermosetting resin of the conductive members 30. As a result, the thermoplastic resin of the support body 10 does not melt even when the thermosetting resin of the conductive members 30 reaches the curing temperature, making it easier to inhibit degradation of the light reflectivity of the support body 10. An epoxy resin can be used as the thermosetting resin of the conductive members 30, and polyethylene terephthalate can be used as the thermoplastic resin of the support body 10. The curing temperature of the epoxy resin is not less than about 100 °C and not more than about 150 °C. The melting point of the polyethylene terephthalate is about 250 °C.

The conductive members 30 include the first conductive member 31 and the second conductive member 32. The first conductive member 31 includes the first part 31A and the second part 31B. The first part 31A is positioned in the first through-hole 11H. The second part 31B is continuous with the first part 31A. The second part 31B is positioned closer to the second surface 102 of the support body 10 than the first surface 101. The second part 31B does not include a portion of the first conductive member 31 positioned in the first through-hole 11H. The first conductive member 31 is electrically connected to the first electrode 21 of the light source part 20. The first conductive member 31 of the present embodiment is in contact with the first electrode 21. The second part 31B of the present embodiment covers a portion of the second surface 102 of the support body 10 and at least a portion of the lower surface of the first part 31A. The first conductive member 31 includes the first region 31R1 that overlaps the insulating member 40, which is described below, when viewed from the second surface 102 side, and includes the second region 31R2 that does not overlap the insulating member 40 when viewed from the second surface 102 side. In the specification, the phrase "when viewed from the second surface side" is synonymous with the bottom view.

The second conductive member 32 includes the third part 32A and the fourth part 32B. The third part 32A is positioned in the second through-hole 12H. The fourth part 32B is continuous with the third part 32A. The fourth part 32B is positioned closer to the second surface 102 side of the support body 10 than to the first surface 101. The fourth part 32B does not include a portion of the second conductive member 32 positioned in the second through-hole 12H. The second conductive member 32 is electrically connected to the second electrode 22 of the light source part 20. The second conductive member 32 of the present embodiment is in contact with the second electrode 22. The fourth part 32B of the present embodiment covers a portion of the second surface 102 of the support body 10 and at least a portion of the lower surface of the third part 32A. The second conductive member 32 includes a third region 32R1 that overlaps the insulating member 40 when viewed from the second surface 102 side and a fourth region 32R2 that does not overlap the insulating member 40 when viewed from the second surface 102 side. In the present embodiment, the first conductive member 31 and the second conductive member 32 are arranged in the first direction.

### Insulating member 40

The insulating member 40 is an insulating member that covers portions of the conductive members 30. The material of the insulating member 40 is not particularly limited. A sheet-like optically clear adhesive, resist, etc., can be used as the material of the insulating member 40. The insulating member 40 may include a single layer in the vertical direction, or may include a stacked body of multiple layers. For example, the insulating member 40 may include a single-layer optically clear adhesive, or may include a stacked body of an optically clear adhesive and a resist. It is favorable for the insulating member 40 to be adhesive. As a result, when the light-emitting device 1000 is mounted to a wiring substrate, it is easier to increase the bonding strength between the light-emitting device 1000 and the wiring substrate by the insulating member 40 contacting the wiring substrate.

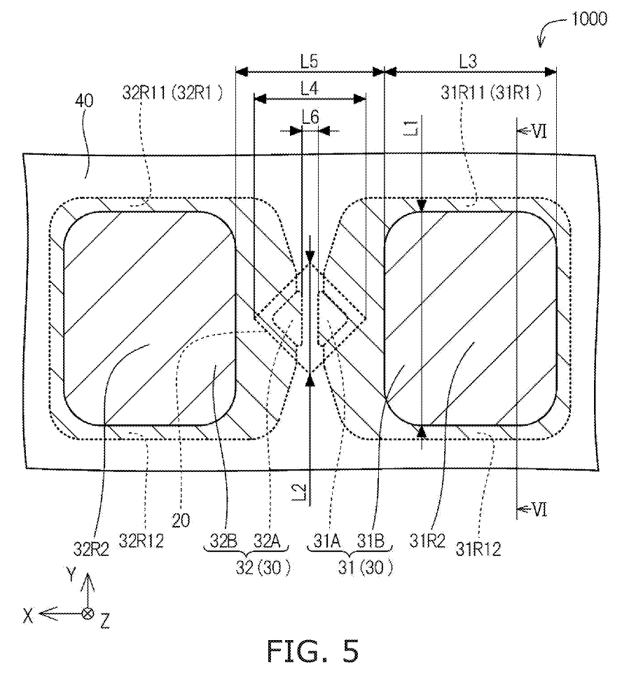

As shown in FIG. 5, the insulating member 40 overlaps at least a portion of the first part 31A of the first conductive member 31 when viewed from the second surface side. In the present embodiment, the insulating member 40 overlaps the entire first part 31A of the first conductive member 31 when viewed from the second surface side. A portion of the first conductive member 31 is not covered with the insulating member 40 when viewed from the second surface 102 side. The first conductive member 31 includes the first region 31R1 and the second region 31R2. The first region 31R1 of the first conductive member 31 is a region that overlaps the insulating member 40 when viewed from the second surface 102 side. The second region 31R2 of the first conductive member 31 is a region that does not overlap the insulating member 40 when viewed from the second surface 102 side. In FIG. 5, the area of the first region 31R1 is illustrated by upper right oblique hatching, and the area of the second region 31R2 is illustrated by upper left oblique hatching.

As shown in FIG. 5, the insulating member 40 overlaps at least a portion of the third part 32A of the second conductive member 32 when viewed from the second surface side. In the present embodiment, the insulating member 40 overlaps the entire third part 32A of the second conductive member 32 when viewed from the second surface side. A portion of the second conductive member 32 is not covered with the insulating member 40 when viewed from the second surface 102 side. The second conductive member 32 includes the third region 32R1 and the fourth region 32R2. The third region 32R1 of the second conductive member 32 is a region overlapping the insulating member 40 when viewed from the second surface 102 side. The fourth region 32R2 of the second conductive member 32 is a region not overlapping the insulating member 40 when viewed from the second surface 102 side. In FIG. 5, the area of the third region 32R1 is illustrated by upper right oblique hatching, and the area of the fourth region 32R2 is illustrated by upper left oblique hatching.

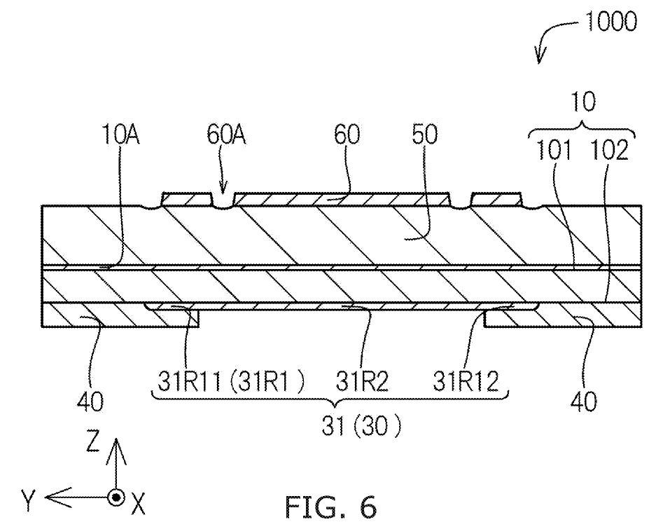

As shown in FIGS. 5 and 6, it is favorable for at least a portion of the second region 31R2 to be positioned between portions of the first region 31R1 in the second direction (the Y-direction). This facilitates an increase in the volume of the first conductive member 31 compared to when the second region 31R2 of the first conductive member 31 is not positioned between portions of the first region 31R1 in the second direction. As a result, the heat that is emitted by the light source part 20 can be transferred more easily to the first conductive member 31, which can inhibit a temperature rise of the light source part 20. This facilitates an increase in reliability of the light-emitting device 1000.

At least a portion of the second region 31R2 need not be positioned between portions of the first region 31R1 in the second direction.

In the present embodiment, as shown in FIGS. 5 and 6, the first region 31R1 includes a first-region first part 31R11 positioned at the +Y side relative to at least a portion of the second region 31R2, and a first-region second part 31R12 positioned at the -Y side relative to the at least a portion of the second region 31R2. It is favorable for at least a portion of the second region 31R2 to be positioned between the first-region first part 31R11 and the first-region second part 31R12 in the second direction (the Y-direction). This facilitates an increase in the volume of the first conductive member 31. As a result, the heat that is emitted by the light source part 20 can be transferred more easily to the first conductive member 31, which can inhibit a temperature rise of the light source part 20.

As shown in FIG. 5, it is favorable for at least a portion of the fourth region 32R2 to be positioned between portions of the third region 32R1 in the second direction. This facilitates an increase in the volume of the second conductive member 32 compared to when the fourth region 32R2 of the second conductive member 32 is not positioned between portions of the third region 32R1 in the second direction. As a result, the heat that is emitted by the light source part 20 can be transferred more easily to the second conductive member 32, which can inhibit a temperature rise of the light source part 20. This facilitates an increase in reliability of the light-emitting device 1000. At least a portion of the fourth region 32R2 is not necessarily positioned between portions of the third region 32R1 in the second direction.

In the present embodiment, as shown in FIG. 5, the third region 32R1 includes a third-region first part 32R11 positioned at the +Y side relative to at least a portion of the fourth region 32R2, and a third-region second part 32R12 positioned at the -Y side relative to at least a portion of the fourth region 32R2. It is favorable for at least a portion of the fourth region 32R2 to be positioned between the third-region first part 32R11 and the third-region second part 32R12 in the second direction (the Y-direction). This facilitates an increase in the volume of the second conductive member 32. As a result, the heat that is emitted by the light source part 20 can be transferred more easily to the second conductive member 32, which can inhibit a temperature rise of the light source part 20.

As shown in FIG. 5, it is favorable for at least a portion of the second region 31R2 to be positioned between portions of the first region 31R1 in the first direction (the X-direction). In other words, it is favorable for at least a portion of the second region 31R2 to be positioned between a portion of the first region 31R1 positioned at the +X side in the first direction (the X-direction) and a portion of the first region 31R1 positioned at the -X side in the first direction (the X-direction). This facilitates an increase in the volume of the first conductive member 31 compared to when the second region 31R2 of the first conductive member 31 is not positioned between portions of the first region 31R1 in the first direction. As a result, the heat that is emitted by the light source part 20 can be transferred more easily to the first conductive member 31, which can inhibit a temperature rise of the light source part 20. This facilitates an increase in reliability of the light-emitting device 1000. At least a portion of the second region 31R2 is not necessarily positioned between portions of the first region 31R1 in the first direction.

As shown in FIG. 5, it is favorable for at least a portion of the fourth region 32R2 to be positioned between portions of the third region 32R1 in the first direction (the X-direction). In other words, it is favorable for at least a portion of the fourth region 32R2 to be positioned between a portion of the third region 32R1 positioned at the +X side in the first direction (the X-direction) and a portion of the third region 32R1 positioned at the -X side in the first direction (the X-direction). This facilitates an increase in the volume of the second conductive member 32 compared to when the fourth region 32R2 of the second conductive member 32 is not positioned between portions of the third region 32R1 in the first direction. As a result, the heat that is emitted by the light source part 20 can be transferred more easily to the second conductive member 32, which can inhibit a temperature rise of the light source part 20. This facilitates an increase in reliability of the light-emitting device 1000. At least a portion of the fourth region 32R2 is not necessarily positioned between portions of the third region 32R1 in the first direction.

As shown in FIG. 5 it is favorable for the entire perimeter of the second region 31R2 to be surrounded with the first region 31R1. In other words, it is favorable for the second region 31R2 to be surrounded with the first region 31R1 without a break. This facilitates an increase in the volume of the first conductive member 31 compared to when the entire perimeter of the second region 31R2 is not surrounded with the first region 31R1. As a result, the heat that is emitted by the light source part 20 can be transferred more easily to the first conductive member 31, which can inhibit a temperature rise of the light source part 20. This facilitates an increase in reliability of the light-emitting device 1000.

As shown in FIG. 5, it is favorable for the entire perimeter of the fourth region 32R2 to be surrounded with the third region 32R1. In other words, it is favorable for the fourth region 32R2 to be surrounded with the third region 32R1 without a break. This facilitates an increase in the volume of the second conductive member 32 compared to when the entire perimeter of the fourth region 32R2 is not surrounded with the third region 32R1. As a result, the heat that is emitted by the light source part 20 can be transferred more easily to the second conductive member 32, which can inhibit a temperature rise of the light source part 20. This facilitates an increase in reliability of the light-emitting device 1000.

As shown in FIG. 5, it is favorable for a maximum length L1 of the second region 31R2 in the second direction (the Y-direction) to be greater than a maximum length L2 of the light source part 20 in the second direction. This facilitates an increase in the volume of the first conductive member 31. As a result, the heat that is emitted by the light source part 20 is transferred more easily to the first conductive member 31. It is favorable for the maximum length of the fourth region 32R2 in the second direction to be greater than the maximum length of the light source part 20 in the second direction. This facilitates an increase in the volume of the second conductive member 32. As a result, the heat that is emitted by the light source part 20 is transferred more easily to the second conductive member 32.

As shown in FIG. 5, it is favorable for a maximum length L3 of the second region 31R2 in the first direction (the X-direction) to be greater than a maximum length L4 of the light source part 20 in the first direction. This facilitates an increase in the volume of the first conductive member 31. As a result, the heat that is emitted by the light source part 20 is transferred more easily to the first conductive member 31. It is favorable for the maximum length of the fourth region 32R2 in the first direction to be greater than the maximum length of the light source part 20 in the first direction. This facilitates an increase in the volume of the second conductive member 32. As a result, the heat that is emitted by the light source part 20 is transferred more easily to the second conductive member 32.

As shown in FIG. 5, it is favorable for a minimum length L5 from the second region 31R2 to the fourth region 32R2 to be greater than a minimum length L6 from the first part 31A to the third part 32A when viewed from the second surface side. As a result, when the light-emitting device 1000 is mounted to a wiring substrate, it is easier to inhibit contact between a first conductive body that electrically connects the second region 31R2 and the wiring substrate and a second conductive body that electrically connects the fourth region 32R2 and the wiring substrate. As a result, it is easier to inhibit a short-circuit of the light-emitting device 1000. This facilitates an increase in reliability of the light-emitting device 1000. It is favorable for the minimum length L5 from the second region 31R2 to the fourth region 32R2 to be greater than the maximum length L4 of the light source part 20 in the first direction when viewed from the second surface side. As a result, when the light-emitting device 1000 is mounted to the wiring substrate, it is easier to inhibit contact between the first conductive body that electrically connects the second region 31R2 and the wiring substrate and the second conductive body that electrically connects the fourth region 32R2 and the wiring substrate.

As shown in FIG. 5, it is favorable for the entire light source part 20 to overlap the insulating member 40 when viewed from the second surface side. As a result, the light source part 20 is protected more easily by the insulating member 40. This facilitates an increase in reliability of the light-emitting device 1000. By the entire light source part 20 overlapping the insulating member 40, it is easier to increase the minimum length L5 from the second region 31R2 to the fourth region 32R2. As a result, when the light-emitting device 1000 is mounted to the wiring substrate, the first conductive body, which electrically connects the second region 31R2 and the wiring substrate, and the second conductive body, which electrically connects the fourth region 32R2 and the wiring substrate, are less likely to come into contact with each other. By the entire light source part 20 overlapping the insulating member 40 when viewed from the second surface side, it is easier to increase the area of the insulating member 40 positioned below the light source part 20. When the insulating member 40, which is adhesive, is in contact with the support body 10, the first conductive member 31, and/or the second conductive member 32, it is easier to increase the contact area of the insulating member 40 with the support body 10, the first conductive member 31, and/or the second conductive member 32. As a result, it is easier to improve the adhesion of the insulating member 40 with the support body 10, the first conductive member 31, and/or the second conductive member 32.

### Light-transmitting member 50

As shown in FIGS. 2 and 3, the light-emitting device 1000 includes the light-transmitting member 50. The light-transmitting member 50 is a member that is transmissive to the light emitted by the light source part 20. The light-transmitting member 50 covers the side surface of the light source part 20. It is favorable for the optical transmittance of the light-transmitting member 50 to the light emission peak wavelength of the light source part 20 to be, for example, not less than 60%, and more favorably not less than 80%. As a result, it is easier to increase the light extraction efficiency of the light-emitting device 1000. As shown in FIG. 3, it is favorable for the light-transmitting member 50 to contact the side surface of the light source part 20. As a result, the light from the light source part 20 is incident on the light-transmitting member 50 more easily. For example, a thermosetting resin such as an epoxy resin, a silicone resin, etc., can be used as the material of the light-transmitting member 50.

The light-transmitting member 50 of the present embodiment covers at least a portion of the upper surface of the light source part 20. By the light-transmitting member 50 covering at least a portion of the upper surface of the light source part 20, it is easier to modulate the luminance in the region directly above the light source part 20. For example, the luminance in the region directly above the light source part 20 can be modulated by modifying the thickness of the light-transmitting member 50 at the portion covering the upper surface of the light source part 20. As a result, it is easier to modulate the luminance, making it easier to reduce uneven luminance of the light-emitting device 1000. By the light-transmitting member 50 covering the entire upper surface of the light source part 20, it is even easier to modulate the luminance in the region directly above the light source part 20. The entire upper surface of the light source part 20 may be exposed from under the light-transmitting member 50. As a result, it is easier to make the light-emitting device 1000 smaller in the vertical direction.

As shown in FIG. 1, the light-transmitting member 50 of the present embodiment is partitioned by a partitioning trench 50G. One region partitioned by the partitioning trench 50G is referred to as a light-emitting region 100A. In the present embodiment, a first light-transmitting part 51S, a second light-transmitting part 52S, a third light-transmitting part 53S, and a fourth light-transmitting part 54S that are partitioned by the partitioning trench 50G are mutually different light-emitting regions 100A. The light-transmitting member 50 includes the first light-transmitting part 51S, the second light-transmitting part 52S, the third light-transmitting part 53S, and the fourth light-transmitting part 54S. One light-emitting region 100A can be used as a driving unit of local dimming. The number of the light-emitting regions 100A included in the light-emitting device 1000 is not particularly limited. For example, the light-emitting device 1000 may include one light-emitting region 100A, or the light-emitting device 1000 may include multiple light-emitting regions 100A. A light-emitting device that has a larger area may be formed by arranging the multiple light-emitting devices 1000. A member that is reflective to the light emitted by the light source part 20 may be located in the partitioning trench 50G. As a result, the contrast between the light-emitting region in the light-emitting state and the light-emitting region in the non-light-emitting state can be improved. In the light-emitting device, a member that is reflective to the light emitted by the light source part 20 may not be located in the partitioning trench 50G. A lens-shaped light-transmitting member 50 may cover the light source part 20.

When the light-emitting device 1000 includes the multiple light-emitting regions 100A, the shapes of the light-emitting regions in a top view may be the same or different from each other. For example, the shapes of the light-emitting regions 100A positioned at the outer perimeter vicinity of the light-emitting device 1000 may be triangular, hexagonal, octagonal, etc., and the shapes of the light-emitting regions 100A positioned at the center vicinity of the light-emitting device 1000 may be quadrilateral.

As shown in FIG. 1, the light-transmitting member 50 of the present embodiment includes the lattice-shaped partitioning trench 50G that includes a first partitioning trench 51G extending in the Y-direction and a second partitioning trench 52G extending in the X-direction. The first partitioning trench 51G that extends in the Y-direction is between the first light-transmitting part 51S and the second light-transmitting part 52S. The second partitioning trench 52G that extends in the X-direction is between the first light-transmitting part 51S and the third light-transmitting part 53S. The direction in which the partitioning trench 50G extends may be oblique to the X-direction and Y-direction.

It is favorable for the partitioning trench 50G to extend from the upper surface to the lower surface of the light-transmitting member 50. As a result, the light-transmitting member 50 can be separated into multiple light-transmitting members 50. As a result, it is easier to reduce warp of the light-transmitting member 50 and/or the support body 10 due to a difference between the thermal expansion coefficient of the light-transmitting member 50 and the thermal expansion coefficient of the support body 10. The partitioning trench 50G may be a recess that is open only at the upper surface side of the light-transmitting member 50, or may be a recess that is open only at the lower surface side of the light-transmitting member 50. When the partitioning trench 50G is a recess, the partitioning trench 50G includes a bottom surface formed of the light-transmitting member 50. The side surface of the partitioning trench 50G may be parallel to the Z-axis direction or oblique to the Z-axis direction. When the side surface of the partitioning trench 50G is oblique to the Z-axis direction, the facing side surfaces of the partitioning trench 50G may be configured so that the distance between the facing side surfaces decreases or increases downward. The outer side surface of the light-transmitting member 50 that defines the outer perimeter of the light-emitting device may be parallel to the Z-axis direction or oblique to the Z-axis direction. When the light-emitting device does not include a light-transmitting member, the light-emitting regions may be partitioned by a reflecting member surrounding the light source parts.

As shown in FIG. 3, it is favorable for the light-transmitting member 50 to include a hole part (hereinbelow, referred to as a light-transmitting hole part 50A) that is open at the upper surface and/or the lower surface of the light-transmitting member 50. In the present embodiment, the light-transmitting hole part 50A is a recess that is open only at the upper surface side of the light-transmitting member 50. The light-transmitting hole part 50A may be a recess that is open only at the lower surface side of the light-transmitting member 50, or may be a through-hole that extends from the upper surface to the lower surface of the light-transmitting member 50. By the light-transmitting member 50 including the light-transmitting hole part 50A, the surface area of the light-transmitting member 50 can be increased. As a result, the amount of light extracted outside the light-transmitting member 50 from the surface of the light-transmitting member 50 can be increased. As a result, it is easier to modulate the luminance of the light-emitting device 1000, making it easier to reduce uneven luminance of the light-emitting device 1000. The depth of the recess in the vertical direction is, for example, not less than 0.1 times the maximum length of the light-transmitting member 50 in the vertical direction. The light-transmitting member 50 may include one, two, or more light-transmitting hole parts 50A.

The shape of the light-transmitting hole part 50A in a top view is not particularly limited. As shown in FIG. 2, the light-transmitting hole part 50A may include a linear portion in a top view. In the specification, linear includes straight lines, curves, bent lines, etc. The shape of the light-transmitting hole part 50A in a top view may be a V-shape or an L-shape extending in two directions. The shape of the light-transmitting hole part 50A in a top view may be circular, elliptical, polygonal such as triangular, quadrilateral, hexagonal, octagonal, etc.

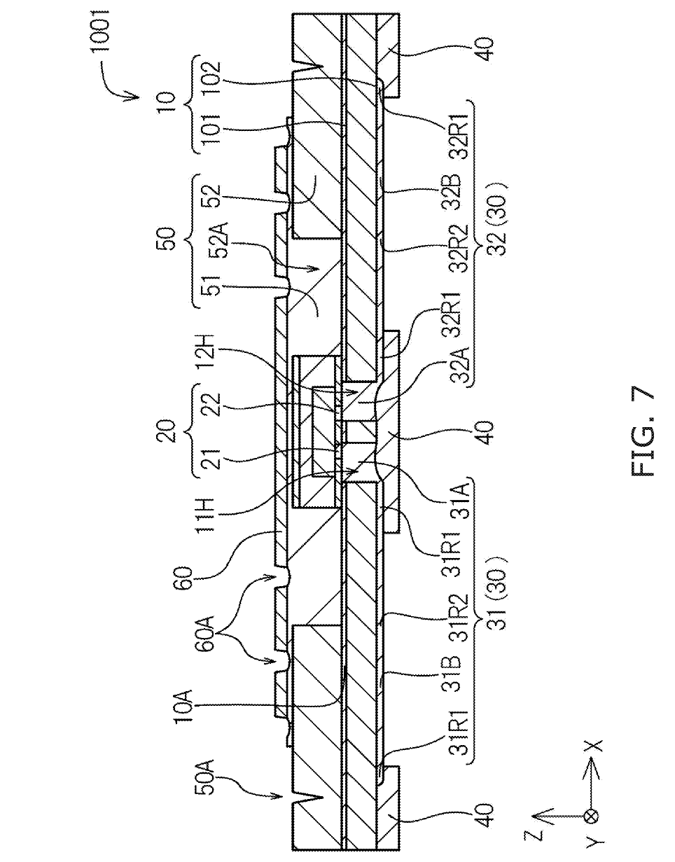

As in a light-emitting device 1001 shown in FIG. 7, the light-transmitting member 50 may include a first light-transmitting member 51 and a second light-transmitting member 52. The second light-transmitting member 52 includes a through-hole (hereinbelow, referred to as a light-transmitting through-hole 52A). The light-transmitting through-hole 52A extends from the upper surface to the lower surface of the second light-transmitting member 52. The light source part 20 and the first light-transmitting member 51 are positioned in the light-transmitting through-hole 52A. The first light-transmitting member 51 is in contact with the light source part 20 and the light-transmitting member 50. The materials of the first and second light-transmitting members 51 and 52 may be the same or different from each other. For example, a thermosetting resin such as an epoxy resin, a silicone resin, etc., may be used as the material of the first light-transmitting member 51, and a thermoplastic resin such as a polycarbonate resin, etc., may be used as the material of the second light-transmitting member 52.

### Light-modulating member 60

As shown in FIGS. 2 and 3, the light-emitting device 1000 includes a light-modulating member 60. The light-modulating member 60 is reflective and transmissive to the light emitted by the light source part 20. A portion of the light emitted from the light source part 20 is reflected by the light-modulating member 60, and another portion of the light is transmitted by the light-modulating member 60. The transmittance of the light-modulating member 60 for the light emission peak wavelength of the light source part 20 is less than the transmittance of the light-transmitting member 50 for the light emission peak wavelength of the light source part 20. For example, it is favorable for the transmittance of the light-modulating member 60 for the light emission peak wavelength of the light source part 20 to be, for example, not less than 1% and not more than 50%, and more favorably not less than 3% and not more than 30%. The light-modulating member 60 may be a single layer in the vertical direction, or may be a stacked body of multiple layers. The light-modulating member 60 can include a resin member, and a reflector included in the resin member. For example, a material similar to the resin material of the support body 10 can be used as the resin member of the light-modulating member 60. A material similar to the reflector of the support body 10 can be used as the material of the reflector of the light-modulating member 60. The light-emitting device may not include the light-modulating member 60.

As shown in FIG. 3, the light-modulating member 60 of the present embodiment is positioned above the light source part 20. The light source part 20 and a portion of the light-modulating member 60 overlap in a top view, and the light-modulating member 60 is positioned above the light source part 20 at the overlapping portion. By positioning the light-modulating member 60 above the light source part 20, it is easier to inhibit the region directly above the light source part 20 from becoming excessively bright.

It is favorable for the light-modulating member 60 to include a hole part (hereinbelow, referred to as a light-modulating hole part 60A) that is open at the upper surface and/or the lower surface. In the present embodiment, the light-modulating hole part 60A is a through-hole that extends from the upper surface to the lower surface. The light-modulating hole part 60A may be a recess that is open only at the upper surface side of the light-modulating member 60, or may be a recess that is open at only the lower surface side of the light-modulating member 60. By the light-modulating member 60 including the light-modulating hole part 60A, it is easier to modulate the luminance in the region directly above the light-modulating member 60. For example, by modifying the size and/or position of the light-modulating hole part 60A, it is easier to modulate the light from the light source part 20 that is shielded by the light-modulating member 60. As a result, it is easier to modulate the luminance in the region directly above the light-modulating member 60, making it easier to reduce uneven luminance of the light-emitting device 1000.

It is favorable for the light-modulating hole part 60A of the light-modulating member 60 to be positioned distant to the light source part 20 in a top view. As a result, it is easier to inhibit the region directly above the light source part 20 from becoming excessively bright. The shape of the light-modulating hole part 60A in a top view is not particularly limited. As shown in FIG. 2, the shape of the light-modulating hole part 60A of the present embodiment is circular in a top view. The shape of the light-modulating hole part 60A in a top view may include a linear portion. The shape of the light-modulating hole part 60A in a top view may be a V-shape or an L-shape extending in two directions. The shape of the light-modulating hole part 60A in a top view may be elliptical or polygonal such as triangular, quadrilateral, hexagonal, octagonal, etc.

The light-modulating hole part 60A and the light-transmitting hole part 50A may overlap in the vertical direction. In other words, the light-modulating hole part 60A and the light-transmitting hole part 50A may overlap in a top view. With this structure, the light emitted outside the light-emitting device 1000 from the light-transmitting hole part 50A can be inhibited from being shielded by the light-modulating member 60. As a result, it is easier to adjust the luminance of the light-emitting device 1000, making it easier to reduce uneven luminance of the light-emitting device 1000.

### Second embodiment

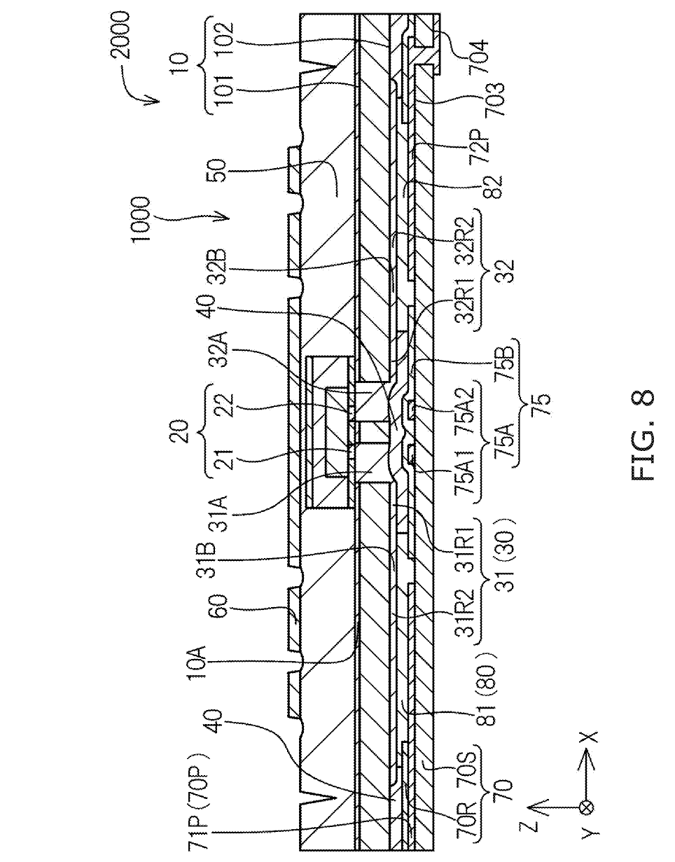

A light-emitting module 2000 according to a second embodiment will now be described with reference to FIGS. 8 to 14. The light-emitting module 2000 according to the second embodiment includes the light-emitting device 1000 according to the first embodiment, a wiring substrate 70, and a conductive body 80. The light-emitting module may include one light-emitting device, or may include multiple light-emitting devices. For example, the light-emitting module may include one light-emitting device on one wiring substrate, or may include multiple light-emitting devices on one wiring substrate. Components included in the light-emitting module 2000 will now be described in detail. The same names and reference numerals as those of the present embodiments above indicate the same or similar members or configurations, and a detailed description is omitted as appropriate.

### Wiring substrate 70

The wiring substrate 70 is a member that supplies power to the light source part 20. The wiring substrate 70 of the present embodiment includes a base member 70S that is insulative, and a wiring part 70P that is conductive. The base member 70S includes a third surface 703 facing the light-emitting device 1000, and a fourth surface 704 positioned at the side opposite to the third surface 703. The base member 70S may be a rigid substrate or a flexible substrate. For example, an epoxy resin, a BT resin, a polyimide resin, etc., can be used as the material of the base member 70S. It is favorable for the base member 70S to be a flexible substrate to make the light-emitting module 2000 smaller in the vertical direction. The base member 70S may be a single layer in the vertical direction, or may be a stacked body of multiple layers. For example, the base member 70S may include a single-layer flexible substrate, or may include a stacked body of multiple rigid substrates. The wiring substrate 70 may include multiple leads, and a resin member that holds the multiple leads.

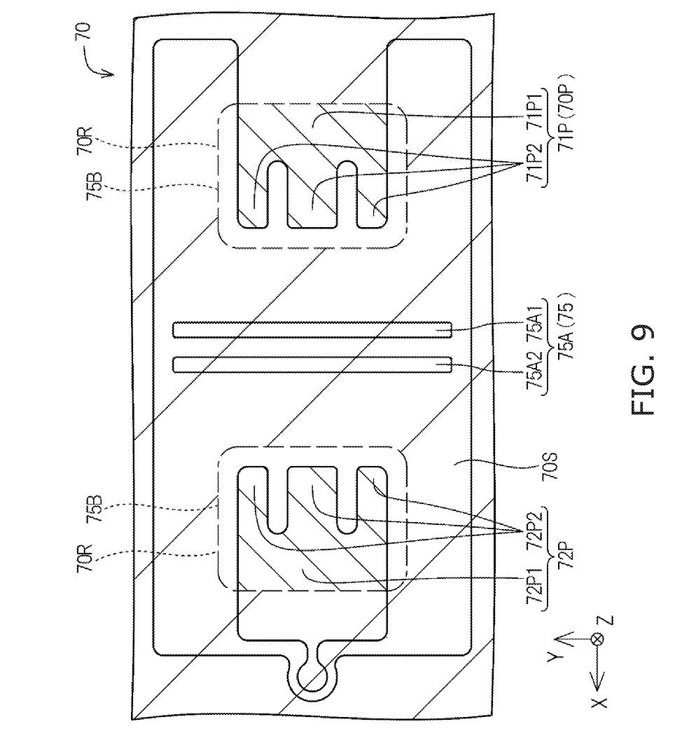

As shown in FIG. 8, the wiring substrate 70 includes the wiring part 70P that is positioned on the third surface 703 of the base member 70S. The number of the wiring parts 70P included in the wiring substrate 70 may be two, three, or more. The wiring part 70P is a metal film such as, for example, a copper film. The wiring part 70P can be formed by a known method such as electroplating, electroless plating, vapor deposition, sputtering, etc. The wiring part 70P of the present embodiment includes a first wiring part 71P and a second wiring part 72P. The wiring substrate 70 of the present embodiment includes a coating layer 70R. At least a portion of the first wiring part 71P is not covered with the coating layer 70R when viewed from the second surface side. In other words, at least a portion of the first wiring part 71P does not overlap the coating layer 70R when viewed from the second surface side. At least a portion of the second wiring part 72P is not covered with the coating layer 70R when viewed from the second surface side. In other words, at least a portion of the second wiring part 72P does not overlap the coating layer 70R when viewed from the second surface side. In FIG. 9, the area in which the coating layer 70R is positioned is illustrated by upper right oblique hatching. In FIG. 9, a portion of the first wiring part 71P and a portion of the second wiring part 72P that are not covered with the coating layer 70R are illustrated by upper left oblique hatching. The coating layer 70R includes, for example, a resist. An acrylic resin or other known material can be used as the resist. The wiring part 70P also may be positioned on the fourth surface 704 of the base member 70S. The light-emitting module 2000 also may include an electronic component such as an integrated circuit or the like electrically connected to the wiring part 70P. The electronic component and the wiring part 70P can be bonded by a known bonding member such as solder, a conductive paste, etc.

The electronic component may be positioned at the third surface side or at the fourth surface side.

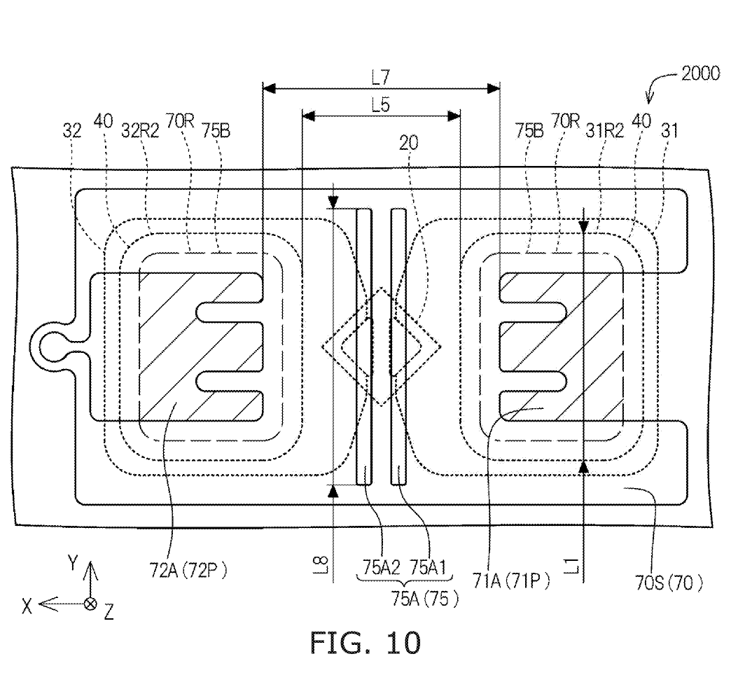

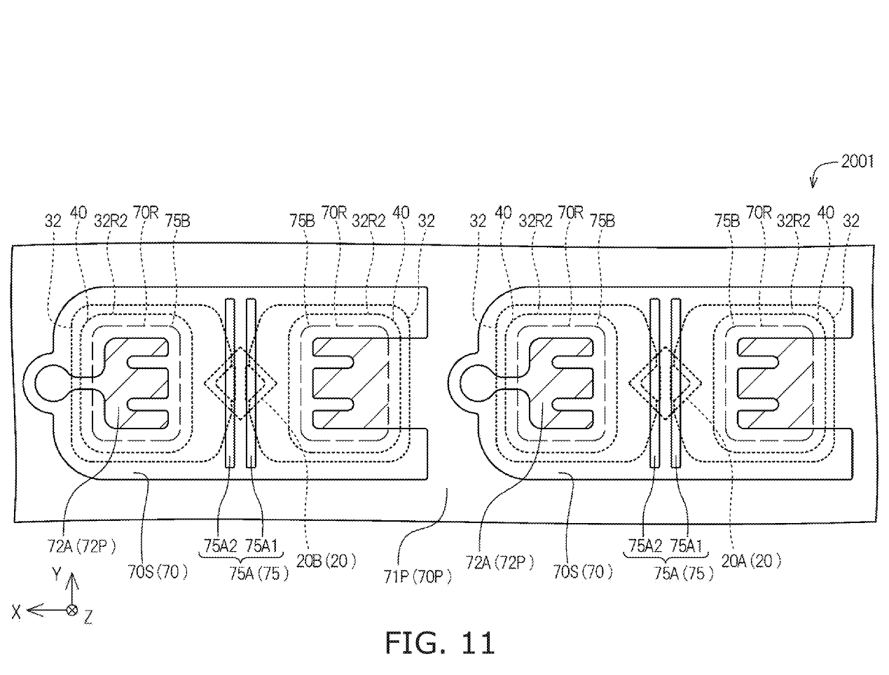

As shown in FIG. 10, it is favorable for the entire perimeter of the second wiring part 72P to be surrounded with the first wiring part 71P. This facilitates an increase in the volume of the first wiring part 71P. As a result, it is easier to reduce the wiring resistance of the first wiring part 71P. When an anode potential is applied to the first wiring part 71P, and a cathode potential is applied to the second wiring part 72P, the anode potential can be inhibited from becoming excessively high due to the wiring resistance by reducing the wiring resistance of the first wiring part 71P. When a light-emitting module 2001 includes multiple second wiring parts 72P as shown in FIG. 11, it is favorable for the entire perimeter of each of the multiple second wiring parts 72P to be surrounded with one first wiring part 71P. This facilitates an increase in the volume of the first wiring part 71P, making it easier to reduce the wiring resistance.

### Conductive body 80

The conductive body 80 is a conductive member that supplies power to the light source part 20. The material of the conductive body 80 is not particularly limited. A material similar to that of the conductive members 30 can be used as the material of the conductive body 80. The conductive body 80 may include a thermosetting resin, and the support body 10 may include a thermoplastic resin. In such a case, it is favorable for the melting point of the thermoplastic resin of the support body 10 to be greater than the curing temperature of the thermosetting resin of the conductive body 80. As a result, the thermoplastic resin of the support body 10 does not melt even when the thermosetting resin of the conductive body 80 reaches the curing temperature, making it easier to inhibit degradation of the light reflectivity of the support body 10. An epoxy resin may be used as the thermosetting resin of the conductive body 80, and polyethylene terephthalate can be used as the thermoplastic resin of the support body 10. Although the method for forming the conductive body 80 that electrically connects the light-emitting device and the wiring substrate is not particularly limited, it is favorable to perform the method while pressing in a vacuum. As a result, it is easier to inhibit the occurrence of voids in the conductive body 80. Only one of pressing or forming in a vacuum may be performed when forming the conductive body 80.

As shown in FIG. 8, the conductive body 80 includes a first conductive body 81 and a second conductive body 82. The first conductive body 81 electrically connects the first conductive member 31 and the first wiring part 71P. The first conductive body 81 of the present embodiment is in contact with the first conductive member 31 and the first wiring part 71P. The first conductive body 81 of the present embodiment is also in contact with the insulating member 40. This facilitates an increase in the volume of the first conductive body 81. As a result, the heat that is emitted by the light source part 20 can be transferred more easily to the first conductive body 81, which can inhibit a temperature rise of the light source part 20. As a result, it is easier to increase the reliability of the light-emitting module 2000. The first conductive body 81 of the present embodiment is in contact with the base member 70S and the coating layer 70R. This facilitates an increase in the volume of the first conductive body 81.

The second conductive body 82 electrically connects the second conductive member 32 and the second wiring part 72P. The second conductive body 82 of the present embodiment is in contact with the second conductive member 32 and the second wiring part 72P. The second conductive body 82 of the present embodiment is also in contact with the insulating member 40. This facilitates an increase in the volume of the second conductive body 82. As a result, the heat that is emitted by the light source part 20 can be transferred more easily to the second conductive body 82, which can inhibit a temperature rise of the light source part 20. The second conductive body 82 of the present embodiment is in contact with the base member 70S and the coating layer 70R. This facilitates an increase in the volume of the second conductive body 82.

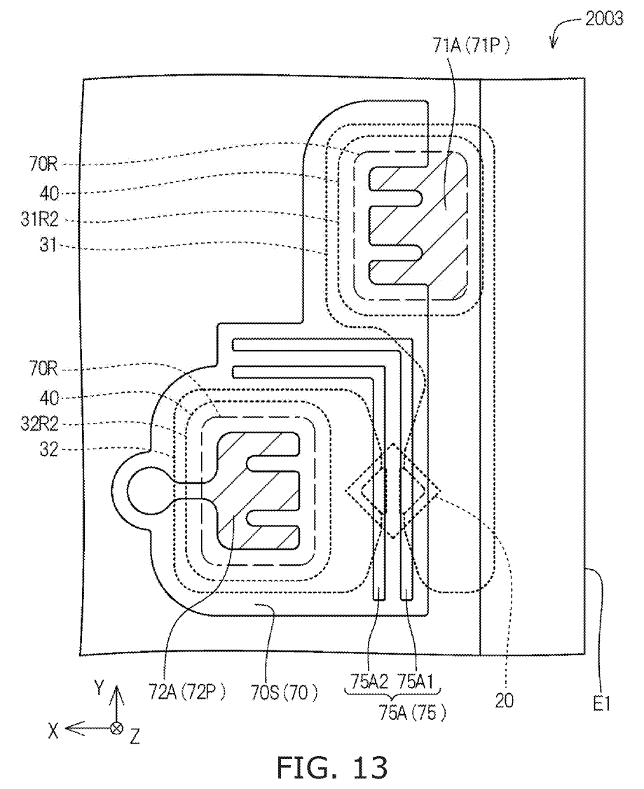

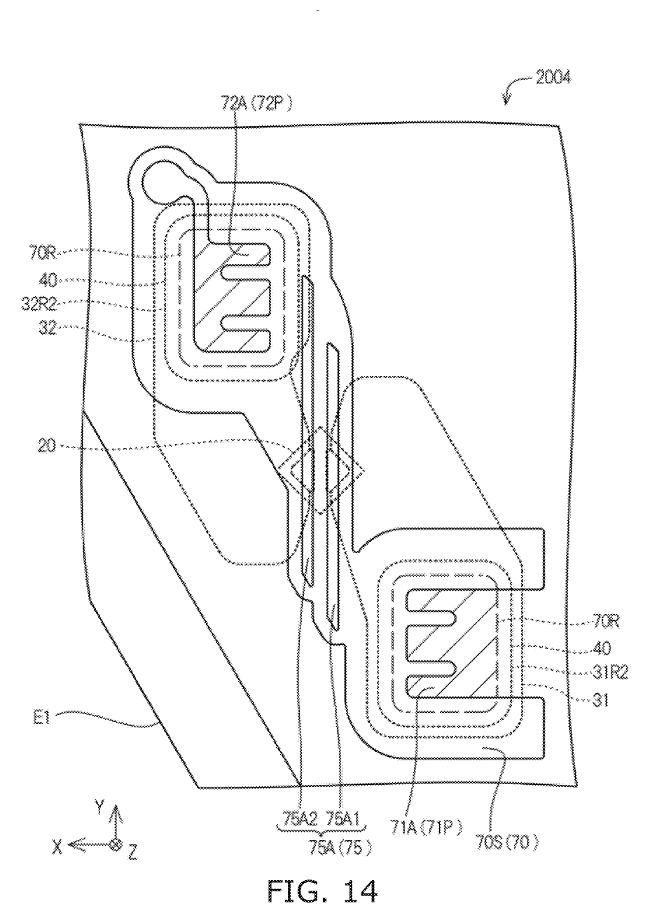

The first wiring part 71P includes a first bonding region 71A that is in contact with the first conductive body 81. The second wiring part 72P includes a second bonding region 72A that is in contact with the second conductive body 82. The area of the first bonding region 71A and the area of the second bonding region 72A are illustrated by upper left oblique hatching in FIGS. 10-12. The area of the first bonding region 71A and the area of the second bonding region 72A are illustrated by upper right oblique hatching in FIGS. 13 and 14.

As shown in FIG. 10, it is favorable for a minimum distance L7 from the first bonding region 71A to the second bonding region 72A to be greater than the minimum length L5 from the second region 31R2 to the fourth region 32R2 when viewed from the second surface side. With this structure the first conductive body 81 and the second conductive body 82 are less likely to come into contact with each other. Accordingly, it is easier to inhibit a short-circuit of the light-emitting module 2000. As a result, it is easier to increase the reliability of the light-emitting module 2000.

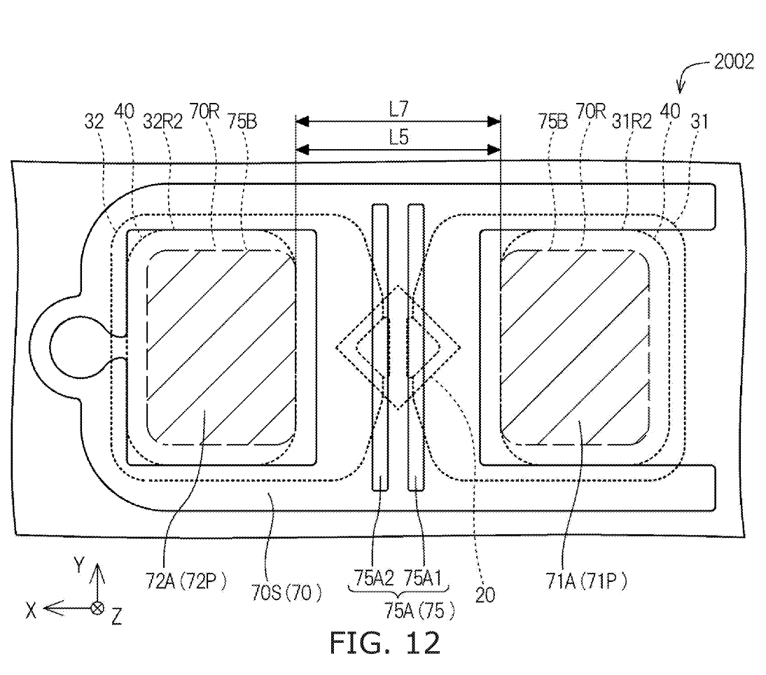

As in a light-emitting module 2002 shown in FIG. 12, the minimum distance L7 from the first bonding region 71A to the second bonding region 72A may be equal to the minimum length L5 from the second region 31R2 to the fourth region 32R2 when viewed from the second surface side. With this structure, when viewed from the second surface side, it is easier to increase the area at which the second region 31R2 and the first bonding region 71A overlap and/or the area at which the fourth region 32R2 and the second bonding region 72A overlap. As a result, the heat that is emitted by the light source part 20 is transferred more easily to the first wiring part 71P and/or the second wiring part 72P. As a result, a temperature rise of the light source part 20 can be inhibited, making it easier to increase the reliability of the light-emitting module 2001.

As shown in FIG. 9, the first wiring part 71P of the present embodiment includes a first wiring-part main part 71P1, and multiple first wiring-part extension parts 71P2 extending from the first wiring-part main part 71P1. The light source part 20 and the first wiring-part main part 71P1 are arranged in the first direction (the X-direction). The first wiring-part main part 71P1 is positioned at the -X side relative to the light source part 20. The multiple first wiring-part extension parts 71P2 is positioned between the light source part 20 and the first wiring-part main part 71P1 in the first direction. Each first wiring-part extension part 71P2 extends in the first direction to approach the light source part 20 from the first wiring-part main part 71P1. By the first wiring part 71P including the multiple first wiring-part extension parts 71P2, it is easier to increase the contact area of the first wiring part 71P and the first conductive body 81. This structure allows for reducing failure to light caused by a poor contact between the first wiring part 71P and the first conductive body 81. As a result, it is easier to increase the reliability of the light-emitting module 2000. It is favorable for the first conductive body 81 to contact the first wiring-part main part 71P1 and the multiple first wiring-part extension parts 71P2. As a result, it is easier to increase the contact area of the first wiring part 71P and the first conductive body 81. The number of the first wiring-part extension parts 71P2 is not particularly limited. For example, the number of the first wiring-part extension parts 71P2 may be two, three, four, or more.

The second wiring part 72P of the present embodiment includes a second wiring-part main part 72P1, and multiple second wiring-part extension parts 72P2 extending from the second wiring-part main part 72P1. The light source part 20 and the second wiring-part main part 72P1 are arranged in the first direction. The second wiring-part main part 72P1 is positioned at the +X side relative to the light source part 20. The multiple second wiring-part extension parts 72P2 are positioned between the light source part 20 and the second wiring-part main part 72P1 in the first direction. Each second wiring-part extension part 72P2 extends in the first direction to approach the light source part 20 from the second wiring-part main part 72P1. By the second wiring part 72P including the multiple second wiring-part extension parts 72P2, it is easier to increase the contact area of the second wiring part 72P and the second conductive body 82. This structure allows for reducing failure to light caused by a poor contact between the second wiring part 72P and the second conductive body 82. As a result, it is easier to increase the reliability of the light-emitting module 2000. It is favorable for the second conductive body 82 to contact the second wiring-part main part 72P1 and the multiple second wiring-part extension parts 72P2. As a result, it is easier to increase the contact area of the second wiring part 72P and the second conductive body 82. The number of the second wiring-part extension parts 72P2 is not particularly limited. For example, the number of the second wiring-part extension parts 72P2 may be two, three, four, or more.

As shown in FIG. 8, the wiring substrate 70 of the present embodiment includes a protrusion 75 positioned at the third surface 703. The protrusion 75 is insulative. As shown in FIG. 9, at least a portion of the protrusion 75 is positioned between the first bonding region 71A and the second bonding region 72A when viewed from the second surface side. Inclusion of the protrusion 75 of the wiring substrate 70 allows for inhibiting the first conductive body 81 and the second conductive body 82 from coming into contact with each other. With this structure, a short-circuit of the light-emitting module 2000 can be inhibited. As a result, it is easier to increase the reliability of the light-emitting module 2000. It is favorable for the insulating member 40 and the protrusion 75 to be in contact with each other. With this structure, the heat that is emitted by the light source part 20 is transferred more easily via the insulating member 40 to the protrusion 75, which is a portion of the wiring substrate 70. Accordingly, a temperature rise of the light source part 20 can be inhibited. As a result, it is easier to increase the reliability of the light-emitting module 2000.

It is favorable for the thickness of the protrusion 75 to be greater than the thickness of the first wiring part 71P. As a result, the first conductive body 81 and the second conductive body 82 are less likely to come into contact with each other. Similarly, it is favorable for the thickness of the protrusion 75 to be greater than the thickness of the second wiring part 72P. In the specification, the thickness of the protrusion 75 is the value when the distance from the third surface 703 of the base member 70S to the upper surface of the protrusion 75 in the vertical direction is a maximum. The thickness of the first wiring part 71P is the value when the distance from the third surface 703 of the base member 70S to the upper surface of the first wiring part 71P in the vertical direction is a maximum. The thickness of the second wiring part 72P is the value when the distance from the third surface 703 of the base member 70S to the upper surface of the second wiring part 72P in the vertical direction is a maximum.

It is favorable for the protrusion 75 to include at least one metal member 75A, and an insulating layer 75B that covers the at least one metal member 75A. A metal member typically has better heat dissipation than a resin or other insulating member, making it easier to improve the heat dissipation of the light-emitting module 2000 by the protrusion including the metal member 75A. It is favorable for the thickness of the metal member to be not less than 0.9 times and not more than 1.1 times the thickness of the first wiring part 71P. As a result, the first wiring part, the second wiring part, and a portion of the protrusion can be easily formed. For example, the first wiring part, the second wiring part, and a portion of the protrusion can be formed in the same process by forming a resist mask on a metal film positioned on the base member 70S and by etching. For example, copper, aluminum, gold, silver, iron, nickel, an alloy of these metals, etc., can be used as the metal member 75A of the protrusion 75. For example, similarly to the coating layer 70R, a resist can be used as the insulating layer 75B of the protrusion 75. In the present embodiment, the insulating layer 75B and the coating layer 70R are the same member. The insulating layer 75B and the coating layer 70R may be separate bodies. In the present embodiment, the upper surface and side surface of the metal member 75A are covered with the insulating layer 75B, and so the first conductive body 81 and the second conductive body 82 do not contact the metal member 75A. With this structure, the first conductive body 81 and the second conductive body 82 can be inhibited from being electrically connected with each other. The protrusion 75 may be formed of a single layer or stacked multiple layers of an insulating member such as a resin, etc.

For example, the protrusion 75 may be formed of the coating layer 70R and a resin layer covering the coating layer 70R.

As shown in FIG. 10, it is favorable for the metal member 75A to include a first metal member 75A1 and a second metal member 75A2 that are arranged in the first direction (the X-direction) and are not electrically connected to each other. For example, even when through-holes are unintentionally formed in the insulating layer 75B, resulting in electrical connection between the first conductive body 81 and the first metal member 75A1 and electrical connection between the second conductive body 82 and the second metal member 75A2, the first conductive body 81 and the second conductive body 82 are less likely to be electrically connected with each other because the first metal member 75A1 and the second metal member 75A2 are not electrically connected to each other. As a result, a short-circuit of the light-emitting module 2000 can be inhibited. As a result, it is easier to increase the reliability of the light-emitting module 2000.

As shown in FIG. 10, when viewed from the second surface side, it is favorable for the first metal member 75A1 to overlap the first conductive member 31, and to be positioned distant to the second conductive member 32. With this structure, even if a through-hole is unintentionally formed in the insulating layer 75B, the first metal member 75A1 and the second conductive member 32 are less likely to be electrically connected to each other. As a result, a short-circuit of the light-emitting module 2000 can be inhibited. When viewed from the second surface side, it is favorable for the second metal member 75A2 to overlap the second conductive member 32, and to be positioned distant to the first conductive member 31. As a result, even if a through-hole is unintentionally formed in the insulating layer 75B, the second metal member 75A2 and the first conductive member 31 are less likely to be electrically connected to each other. It is favorable for the first metal member 75A1 not to overlap the first and second conductive bodies 81 and 82 when viewed from the second surface side. With this structure, even if a through-hole is unintentionally formed in the insulating layer 75B, the first conductive body 81 and the second conductive body 82 are less likely to be electrically connected to each other. It is favorable for the second metal member 75A2 not to overlap the first and second conductive bodies 81 and 82 when viewed from the second surface side. With this structure, even if a through-hole the first conductive body 81 and the second conductive body 82 are less likely to be electrically connected to each other. It is favorable for at least one metal member 75A not to overlap the first and second conductive bodies 81 and 82. It is favorable for the first metal member 75A1 and the second metal member 75A2 to overlap the light source part 20 when viewed from the second surface side. With this structure, the heat that is emitted by the light source part 20 is transferred more easily to the first and second metal members 75A1 and 75A2. Accordingly, a temperature rise of the light source part 20 can be inhibited. As a result, it is easier to increase the reliability of the light-emitting module 2000.

As shown in FIG. 10, it is favorable for a maximum length L8 of the at least one metal member 75A in the second direction to be greater than the maximum length L1 of the second region 31R2 in the second direction. With this structure, the protrusion 75 can inhibit establishment of contact between the first conductive body 81 and the second conductive body 82. As a result, a short-circuit of the light-emitting module 2000 can be inhibited. When there are multiple metal members 75A, the length of metal member 75A in the second direction longest among the multiple metal members 75A is used as the maximum length L8 of the at least one metal member 75A in the second direction.

The shape of the at least one metal member 75A when viewed from the second surface side is not particularly limited. The shape of the at least one metal member 75A when viewed from the second surface side may be linear, including straight lines, curves, bent lines, etc. For example, the at least one metal member 75A may extend linearly in the second direction as shown in FIG. 10, or the at least one metal member 75A may have an L-shape extending in two directions, i.e., the first and second directions, as in a light-emitting module 2003 shown in FIG. 13.

The positions of the light source part 20, the first bonding region 71A, and the second bonding region 72A when viewed from the second surface side are not particularly limited. For example, as shown in FIG. 10, the light source part 20, the first bonding region 71A, and the second bonding region 72A may be arranged in the first direction. As in the light-emitting module 2003 shown in FIG. 13, the light source part 20 and the first bonding region 71A may be arranged in the second direction, and the light source part 20 and the second bonding region 72A may be arranged in the first direction. When an outer edge E1 of the light-emitting module 2003 is positioned at the vicinity of the first bonding region 71A and is positioned at the -X side relative to the first bonding region 71A, by arranging the light source part 20 and the first bonding region 71A in the second direction, it is easier to arrange the light source part 20 proximate to the outer edge E1 of the light-emitting module 2003 without reducing the area of the first bonding region 71A. With this structure, it is easier to increase the degree of freedom of the position of the light source part 20 in the light-emitting module 2003. As in a light-emitting module 2004 shown in FIG. 14, the light source part 20, the first bonding region 71A, and the second bonding region 72A may be arranged in a third direction oblique to the first and second directions. When the outer edge E1 of the light-emitting module 2004 extends parallel to the third direction, by arranging the light source part 20, the first bonding region 71A, and the second bonding region 72A in the third direction, it is easier to arrange the light source part 20 proximate to the outer edge E1 of the light-emitting module 2004 without reducing the areas of the first and second bonding regions 71A and 72A. With this structure, it is easier to increase the degree of freedom of the position of the light source part 20 in the light-emitting module 2004.

### Third embodiment

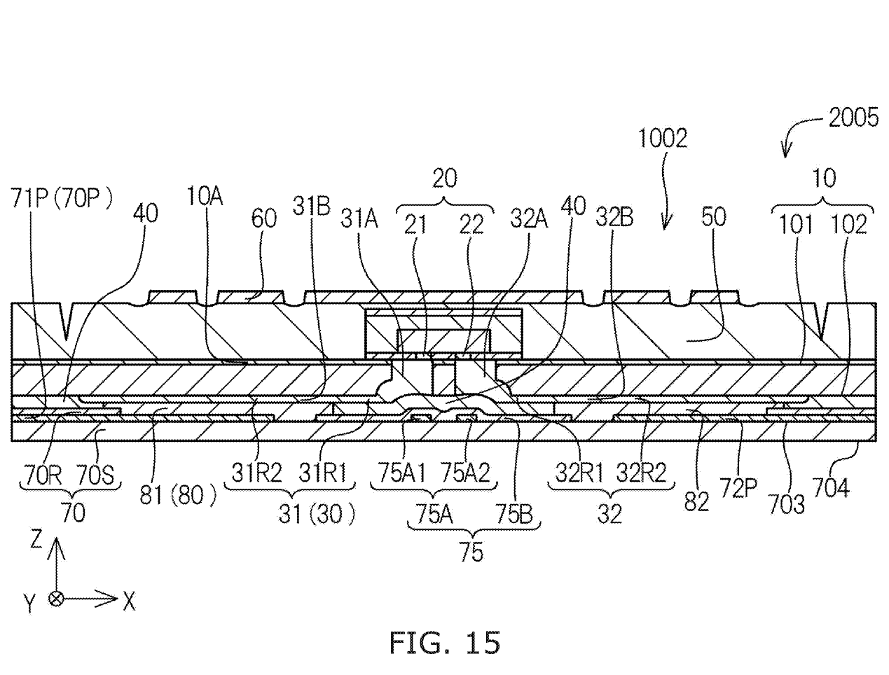

A light-emitting module 2005 according to a third embodiment will now be described with reference to FIGS. 15-22. The light-emitting module 2005 according to the third embodiment as shown in FIG. 15 includes a light-emitting device 1002, the wiring substrate 70, and the conductive body 80. The light-emitting module may include one light-emitting device or multiple light-emitting devices. Mainly the shape of the first conductive member 31 and the shape of the second conductive member 32 of the light-emitting device 1002 of the third embodiment are different from those of the light-emitting device 1000 of the first embodiment. Components included in the light-emitting module 2005 will now be described in detail. The same names and reference numerals as those of the present embodiments above indicate the same or similar members or configurations, and a detailed description is omitted as appropriate.

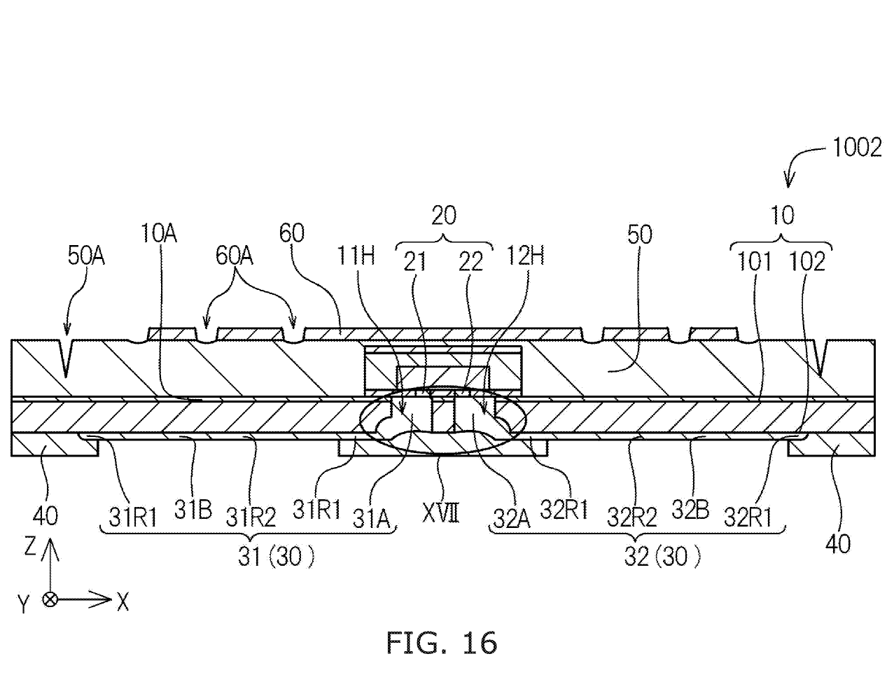

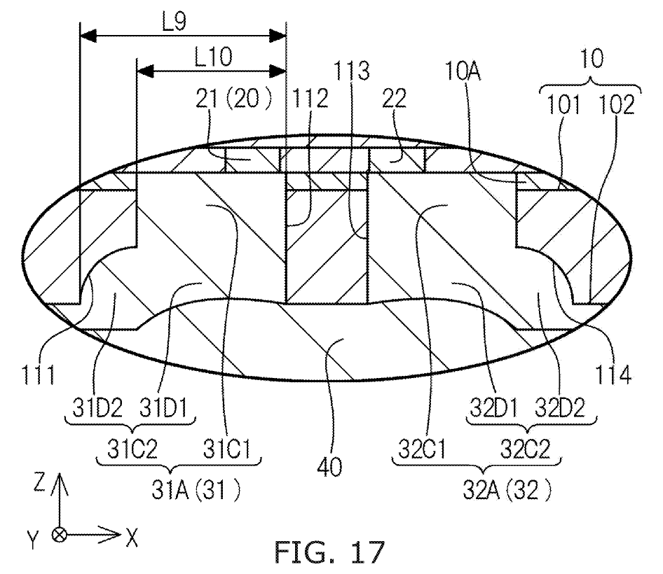

As shown in FIG. 16, the light-emitting device 1002 includes the first conductive member 31 and the second conductive member 32. As shown in FIG. 17, the first part 31A of the first conductive member 31 includes a first conductive part 31C1 and a second conductive part 31C2. The first conductive part 31C1 is positioned at the first surface 101 side of the support body 10. In the specification, "positioned at the first surface 101 side of the support body 10" means positioned in a region including the first surface 101 of the support body 10 when the support body 10 is uniformly trisected into three regions in the vertical direction (the Z-direction). For example, the regions formed by uniformly trisecting the support body 10 in the vertical direction are taken as a first region, a second region, and a third region. The first region is positioned above the second region. The second region is positioned above the third region. The first region includes the first surface 101 of the support body 10. The third region includes the second surface 102 of the support body 10. In the specification, "positioned at the first surface 101 side of the support body 10" means positioned in the first region. The second conductive part 31C2 is positioned at the second surface 102 side of the support body 10. In the specification, "positioned at the second surface 102 side of the support body 10" means positioned in a region including the second surface 102 of the support body 10 when the support body 10 is uniformly trisected into three regions in the vertical direction. For example, similarly to the description above, when the regions formed by uniformly trisecting the support body 10 in the vertical direction are taken as the first, second, and third regions, "positioned at the second surface 102 side of the support body 10" means positioned in the third region.

As shown in FIG. 17, the third part 32A of the second conductive member 32 includes a third conductive part 32C1 and a fourth conductive part 32C2. The third conductive part 32C1 is positioned at the first surface 101 side of the support body 10. The fourth conductive part 32C2 is positioned at the second surface 102 side of the support body 10.

As shown in FIG. 17, it is favorable for a maximum length L9 of the second conductive part 31C2 in the first direction to be greater than a maximum length L10 of the first conductive part 31C1 in the first direction in a first cross section that includes the first and second electrodes 21 and 22 of the light source part 20 and is orthogonal to the first surface 101 of the support body 10. With this structure, it is easier to increase the volume of the first conductive member 31. Accordingly, the heat that is emitted by the light source part 20 can be transferred more easily to the first conductive member 31, which can inhibit a temperature rise of the light source part 20. As a result, it is easier to increase the reliability of the light-emitting device 1002. By increasing the maximum length L9 of the second conductive part 31C2 in the first direction, it is easier to increase the contact area of the first and second parts 31A and 31B. Accordingly, it is easier to inhibit an open-circuit defect (disconnection) due to breakage of the first and second parts 31A and 31B. As a result, it is easier to increase the reliability of the light-emitting device 1002. When the support body 10 is reflective to the light emitted by the light source part 20, it is favorable for the maximum length L10 of the first conductive part 31C1 in the first direction to be less than the maximum length L9 of the second conductive part 31C2 in the first direction. With this structure, it is easier to increase the area of the first surface 101 of the support body 10 than when the maximum length L10 of the first conductive part 31C1 in the first direction is greater than the maximum length L9 of the second conductive part 31C2 in the first direction. Accordingly, the light from the light source part 20 is reflected more easily by the first surface 101 of the support body 10. As a result, it is easier to increase the light extraction efficiency of the light-emitting device 1002. In the specification, "a first cross section" may refer to a cross section including the first and second electrodes 21 and 22 of the light source part 20 and being orthogonal to the first surface 101 of the support body 10.

As shown in FIG. 17, it is favorable for the maximum length of the fourth conductive part 32C2 in the first direction to be greater than the maximum length of the third conductive part 32C1 in the first direction in the first cross section. With this structure, it is easier to increase the volume of the second conductive member 32. Accordingly, the heat that is emitted by the light source part 20 can be transferred more easily to the second conductive member 32, which can inhibit a temperature rise of the light source part 20. As a result, it is easier to increase the reliability of the light-emitting device 1002.

As shown in FIG. 17, the support body 10 includes a first inner side surface 111 and a second inner side surface 112 that define a first through-hole in the first cross section. The first inner side surface 111 and the second inner side surface 112 are positioned in this order in the first direction. The first inner side surface 111 is positioned at the -X side of the second inner side surface 112. It is favorable for the maximum length in the first direction from the first inner side surface 111 to the second inner side surface 112 to be longer at the second surface 102 side than the first surface 101 side in the first cross section. In other words, it is favorable for the maximum length in the first direction from the first inner side surface 111 to the second inner side surface 112 at the second surface 102 side to be greater than the maximum length in the first direction from the first inner side surface 111 to the second inner side surface 112 at the first surface 101 side in the first cross section. With this structure, it is easier to increase the volume of the first part 31A of the first conductive member 31 positioned in the first through-hole. As a result, the heat that is emitted by the light source part 20 is transferred more easily to the first conductive member 31, making it easier to inhibit a temperature rise of the light source part 20. In the light-emitting device 1002, the maximum length in the first direction from the first inner side surface 111 to the second inner side surface 112 at the first surface 101 side is equal to the maximum length L10 of the first conductive part 31C1 in the first direction in the first cross section. In the light-emitting device 1002, the maximum length in the first direction from the first inner side surface 111 to the second inner side surface 112 at the second surface 102 side is equal to the maximum length L9 of the second conductive part 31C2 in the first direction in the first cross section. In the light-emitting device 1002, the first conductive part 31C1 and the second conductive part 31C2 contact the first inner side surface 111 and the second inner side surface 112. The method for forming the first inner side surface 111 and the second inner side surface 112 that define the first through-hole is not particularly limited. For example, the first inner side surface 111 and the second inner side surface 112 can be formed by removing a portion of the support body 10. A known method such as irradiating laser light, cutting, or the like can be used as the method for removing a portion of the support body 10.

As shown in FIG. 17, the support body 10 includes a third inner side surface 113 and a fourth inner side surface 114 that define a second through-hole in the first cross section. The third inner side surface 113 and the fourth inner side surface 114 are positioned in this order in the first direction. The third inner side surface 113 is positioned at the -X side of the fourth inner side surface 114. It is favorable for the maximum length in the first direction from the third inner side surface 113 to the fourth inner side surface 114 to be longer at the second surface 102 side than the first surface 101 side in the first cross section. In other words, it is favorable for the maximum length in the first direction from the third inner side surface 113 to the fourth inner side surface 114 at the second surface 102 side to be greater than the maximum length in the first direction from the third inner side surface 113 to the fourth inner side surface 114 at the first surface 101 side in the first cross section. With this structure, it is easier to increase the volume of the third part 32A of the second conductive member 32 positioned in the second through-hole. As a result, the heat that is emitted by the light source part 20 is transferred more easily to the second conductive member 32, making it easier to inhibit a temperature rise of the light source part 20. In the light-emitting device 1002, the third conductive part 32C1 and the fourth conductive part 32C2 contact the third inner side surface 113 and the fourth inner side surface 114.

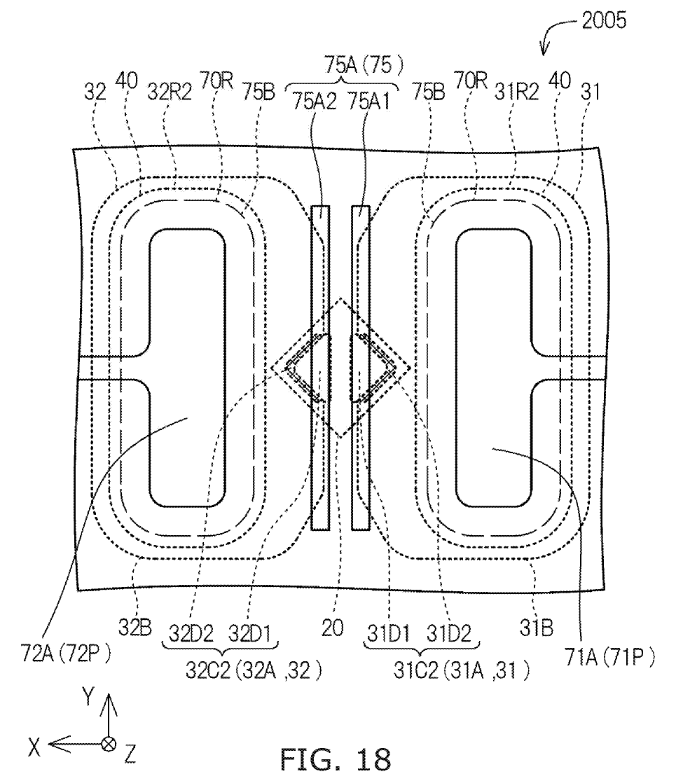

As shown in FIG. 18, it is favorable for the entire second conductive part 31C2 to overlap the insulating member 40 when viewed from the second surface side. With this structure, it is easier to reduce the volume of the first conductive member 31. As a result, it is easier to reduce the material cost of the light-emitting device 1002 and/or the light-emitting module 2005. By the entire second conductive part 31C2 overlapping the insulating member when viewed from the second surface side, it is easier to reduce the area of the second conductive part 31C2 when viewed from the second surface side. For example, when the first inner side surface and the second inner side surface are formed by removing a portion of the support body 10 by irradiating laser light, etc., the area of the second conductive part 31C2 when viewed from the second surface side is reduced, making it easier to reduce the volume of the portion of the support body 10 that is removed. Accordingly, it is easier to reduce the manufacturing time of the light-emitting device 1002 and/or the light-emitting module 2005. As a result, it is easier to reduce the cost of manufacturing the light-emitting device 1002 and/or the light-emitting module 2005. As shown in FIG. 18, it is favorable for the entire second conductive part 31C2 to overlap the light source part 20 when viewed from the second surface side. With this structure, it is easier to reduce the volume of the first conductive member 31. As shown in FIG. 18, it is favorable for the second conductive part 31C2 not to overlap the first wiring part 71P of the wiring substrate 70 when viewed from the second surface side. With this structure, it is easier to reduce the volume of the first conductive member 31.

As shown in FIG. 18, it is favorable for the entire fourth conductive part 32C2 to overlap the insulating member 40 when viewed from the second surface side. With this structure, it is easier to reduce the volume of the second conductive member 32. As a result, it is easier to reduce the material cost of the light-emitting device 1002 and/or the light-emitting module 2005. As shown in FIG. 18, it is favorable for the entire fourth conductive part 32C2 to overlap the light source part 20 when viewed from the second surface side. With this structure, it is easier to reduce the volume of the second conductive member 32. As shown in FIG. 18, it is favorable for the fourth conductive part 32C2 not to overlap the second wiring part 72P of the wiring substrate 70 when viewed from the second surface side. With this structure, it is easier to reduce the volume of the second conductive member 32.

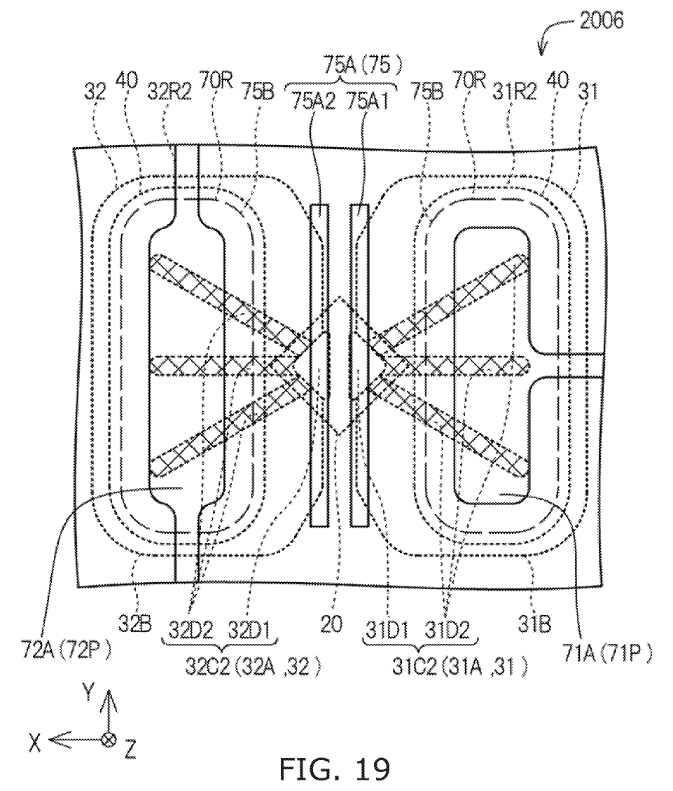

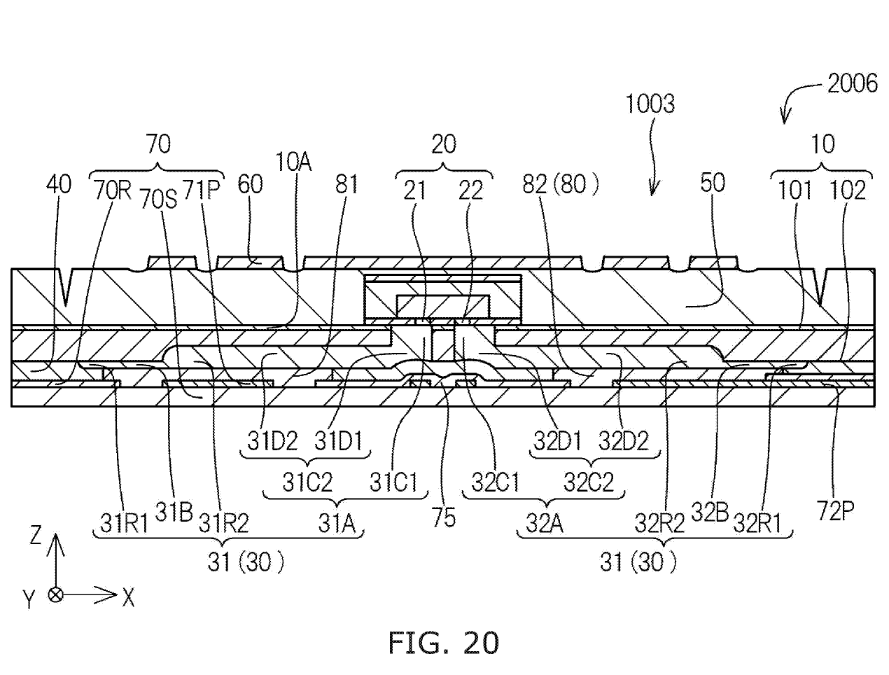

As in a light-emitting module 2006 shown in FIG. 19, a portion of the second conductive part 31C2 may not overlap the insulating member 40 when viewed from the second surface side. With this structure, it is easier to increase the volume of the first conductive member 31. Accordingly, the heat that is emitted by the light source part 20 is transferred more easily to the first conductive member 31, making it easier to inhibit a temperature rise of the light source part 20. As a result, it is easier to increase the reliability of a light-emitting device 1003 and/or the light-emitting module 2006. As shown in FIG. 20, the light-emitting module 2006 includes the light-emitting device 1003, the wiring substrate 70, and the conductive body 80. As shown in FIG. 19, a portion of the second conductive part 31C2 may overlap the first wiring part 71P of the wiring substrate 70 when viewed from the second surface side. With this structure, it is easier to increase the volume of the first conductive member 31.

As shown in FIG. 19, a portion of the fourth conductive part 32C2 may not overlap the insulating member 40 when viewed from the second surface side. With this structure, it is easier to increase the volume of the second conductive member 32. Accordingly, the heat that is emitted by the light source part 20 is transferred more easily to the second conductive member 32, making it easier to inhibit a temperature rise of the light source part 20. As a result, it is easier to increase the reliability of the light-emitting device 1003 and/or the light-emitting module 2006. As shown in FIG. 19, a portion of the fourth conductive part 32C2 may overlap the second wiring part 72P of the wiring substrate 70 when viewed from the second surface side. With this structure, it is easier to increase the volume of the second conductive member 32.

As shown in FIG. 17, the second conductive part 31C2 includes a second conductive main part 31D1 that overlaps the first conductive part 31C1 in the vertical direction (the Z-direction), and a second conductive extension part 31D2 that does not overlap the first conductive part 31C1 in the vertical direction (the Z-direction). In other words, the second conductive part 31C2 includes the second conductive main part 31D1 that overlaps the first conductive part 31C1 when viewed from the second surface side, and the second conductive extension part 31D2 that does not overlap the first conductive part 31C1 when viewed from the second surface side. As shown in FIG. 18, the second conductive extension part 31D2 extends from the second conductive main part 31D1 when viewed from the second surface 102 side. As shown in FIG. 17, it is favorable for the maximum length in the first direction of the second conductive extension part 31D2 positioned at the +X side relative to the second conductive main part 31D1 to be less than the maximum length in the first direction of the second conductive extension part 31D2 positioned at the -X side relative to the second conductive main part 31D1 in the first cross section. With this structure, it is easier to increase the distance from the first conductive member 31 to the second conductive member 32 in the first direction. Accordingly, the first conductive member 31 and the second conductive member 32 are less likely to come into contact with each other. As a result, it is easier to inhibit a short-circuit of the light-emitting device 1002. In the light-emitting device 1002, the second conductive extension part 31D2 is not positioned at the +X side relative to the second conductive main part 31D1. In FIGS. 18, 19, 21, and 22, the area of the second conductive extension part 31D2 is illustrated by cross-hatching.

As shown in FIG. 17, the fourth conductive part 32C2 includes a fourth conductive main part 32D1 that overlaps the third conductive part 32C1 in the vertical direction, and a fourth conductive extension part 32D2 that does not overlap the third conductive part 32C1 in the vertical direction. In other words, the fourth conductive part 32C2 includes the fourth conductive main part 32D1 that overlaps the third conductive part 32C1 when viewed from the second surface side, and the fourth conductive extension part 32D2 that does not overlap the third conductive part 32C1 when viewed from the second surface side. As shown in FIG. 18, the fourth conductive extension part 32D2 extends from the fourth conductive main part 32D1 when viewed from the second surface 102 side. As shown in FIG. 17, it is favorable for the maximum length in the first direction of the fourth conductive extension part 32D2 positioned at the -X side relative to the fourth conductive main part 32D1 to be less than the maximum length in the first direction of the fourth conductive extension part 32D2 positioned at the +X side relative to the fourth conductive extension part 32D2 in the first cross section. With this structure, it is easier to increase the distance from the first conductive member 31 to the second conductive member 32 in the first direction. Accordingly, the first conductive member 31 and the second conductive member 32 are less likely to come into contact with each other. As a result, it is easier to inhibit a short-circuit of the light-emitting device 1002. In the light-emitting device 1002, the fourth conductive extension part 32D2 is not positioned at the -X side relative to the fourth conductive main part 32D1. In FIGS. 18, 19, 21, and 22, the area of the fourth conductive extension part 32D2 is illustrated by cross-hatching.

As shown in FIG. 20, a portion of the second conductive extension part 31D2 may overlap the first wiring part 71P of the wiring substrate 70 in the vertical direction. With this structure, it is easier to increase the volume of the first conductive member 31. Accordingly, the heat that is emitted by the light source part 20 is transferred more easily to the first conductive member 31, making it easier to inhibit a temperature rise of the light source part 20. As a result, it is easier to increase the reliability of the light-emitting device 1003 and/or the light-emitting module 2006. A portion of the fourth conductive extension part 32D2 may overlap the second wiring part 72P of the wiring substrate 70 in the vertical direction. With this structure, it is easier to increase the volume of the second conductive member 32.

One second conductive extension part 31D2 may extend from the second conductive main part 31D1 as shown in FIG. 18, or multiple second conductive extension parts 31D2 may extend from the second conductive main part 31D1 as shown in FIG. 19. When one second conductive extension part 31D2 extends from the second conductive main part 31D1, it is easier to reduce the volume of the first conductive member 31 than when multiple second conductive extension parts 31D2 extend from the second conductive main part 31D1. Accordingly, it is easier to reduce the material cost of the light-emitting device 1002 and/or the light-emitting module 2005. When the multiple second conductive extension parts 31D2 extends from the second conductive main part 31D1, it is easier to increase the volume of the first conductive member 31. Accordingly, the heat that is emitted by the light source part 20 is transferred more easily to the first conductive member 31, making it easier to inhibit a temperature rise of the light source part 20. As a result, it is easier to increase the reliability of the light-emitting device 1003 and/or the light-emitting module 2006. Similarly, one fourth conductive extension part 32D2 may extend from the fourth conductive main part 32D1. With this structure, it is easier to reduce the volume of the first conductive member 31. Multiple fourth conductive extension parts 32D2 may extend from the fourth conductive main part 32D1. With this structure, it is easier to increase the volume of the first conductive member 31.

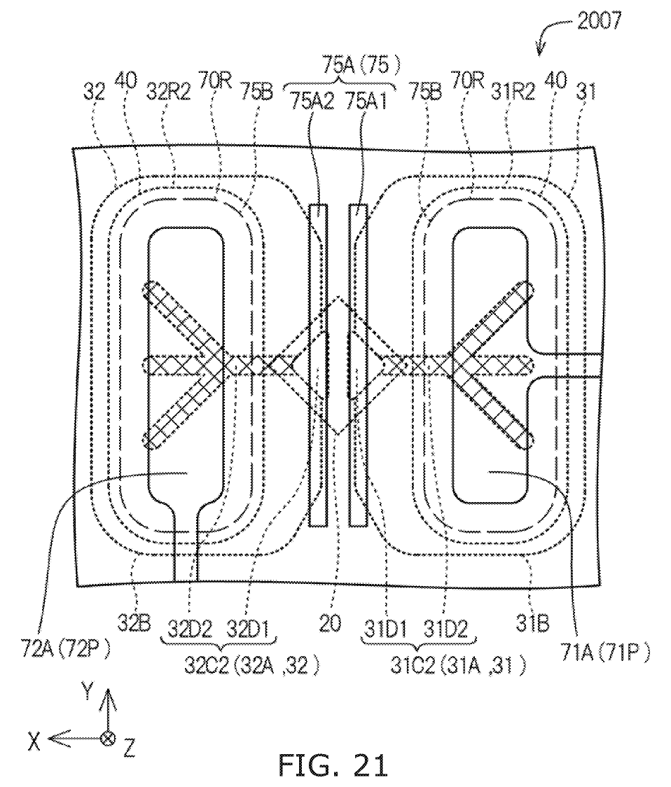

As in a light-emitting module 2007 shown in FIG. 21, one second conductive extension part 31D2 that extends from the second conductive main part 31D1 may branch into multiple branches. With this structure, it is easier to increase the volume of the first conductive member 31. Accordingly, the heat that is emitted by the light source part 20 is transferred more easily to the first conductive member 31, making it easier to inhibit a temperature rise of the light source part 20. One second conductive extension part 31D2 that extends from the second conductive main part 31D1 may not branch into multiple branches. Similarly, one fourth conductive extension part 32D2 that extends from the fourth conductive main part 32D1 may branch into multiple branches. With this structure, it is easier to increase the volume of the second conductive member 32. One fourth conductive extension part 32D2 that extends from the fourth conductive main part 32D1 may not branch into multiple branches.

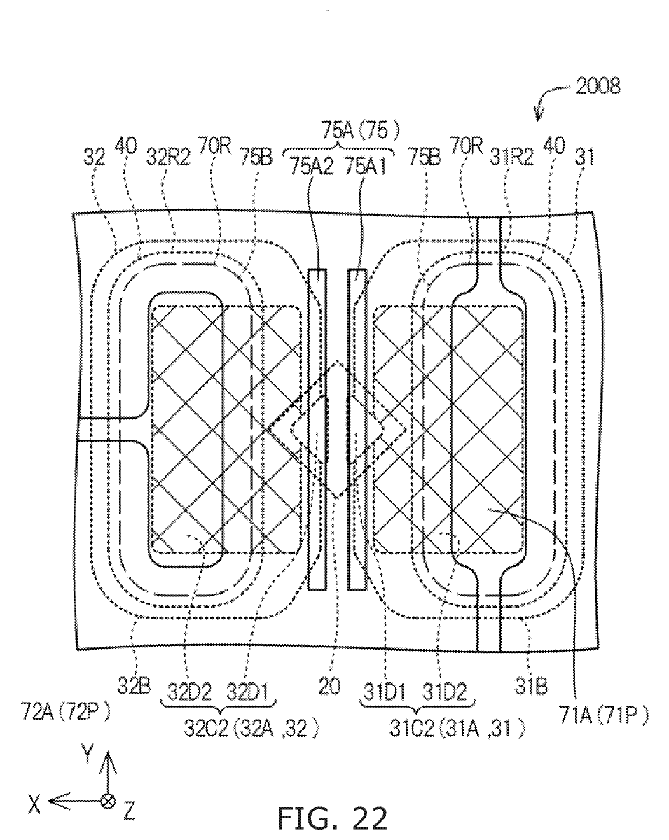

As in a light-emitting module 2008 shown in FIG. 22, the maximum length of the second conductive extension part 31D2 in the second direction may be greater than the maximum length of the second conductive main part 31D1 in the second direction. With this structure, it is easier to increase the volume of the first conductive member 31. Accordingly, the heat that is emitted by the light source part 20 is transferred more easily to the first conductive member 31, making it easier to inhibit a temperature rise of the light source part 20. In the specification, when the second conductive extension part is branched into multiple branches, the length of the second conductive extension part in the second direction is defined as the value when the total of the second-direction lengths of the multiple second conductive extension parts is a maximum. Similarly, the maximum length of the fourth conductive extension part 32D2 in the second direction may be greater than the maximum length of the fourth conductive main part 32D1 in the second direction. With this structure, it is easier to increase the volume of the second conductive member 32. In the specification, when the fourth conductive extension part is branched into multiple branches, the length of the fourth conductive extension part in the second direction is defined as the value when the total of the second-direction lengths of the multiple fourth conductive extension parts is a maximum.

### Fourth embodiment

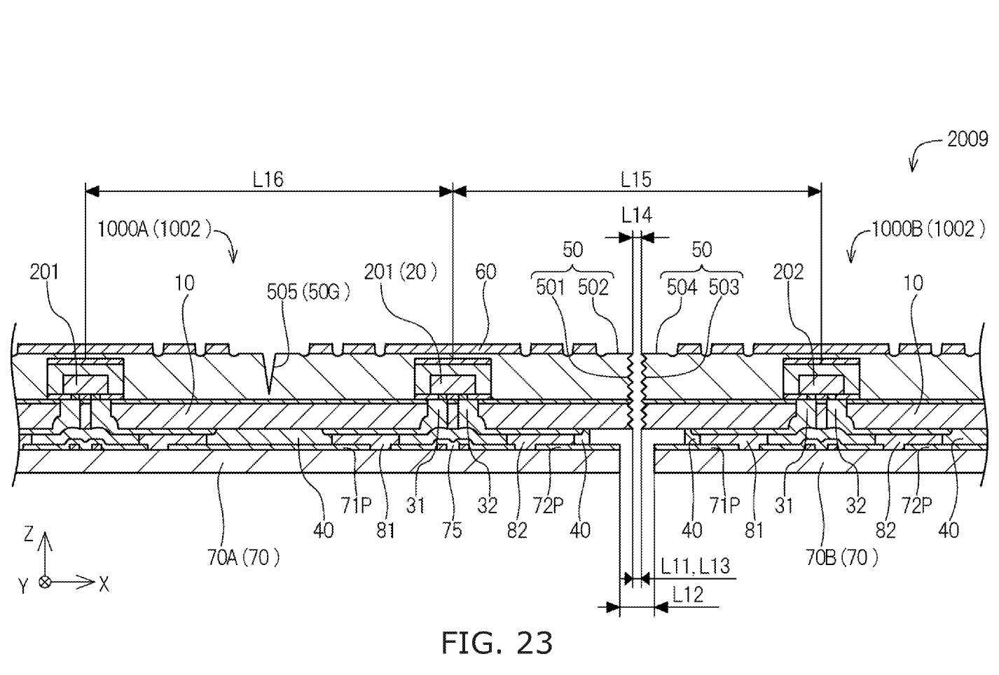

A light-emitting module 2009 according to a fourth embodiment will now be described with reference to FIGS. 23 to 27. As shown in FIG. 23, the light-emitting module 2009 according to the fourth embodiment includes multiple light-emitting devices 1002 and multiple wiring substrates 70. The multiple light-emitting devices 1002 each include the first conductive member 31 and the second conductive member 32. The multiple wiring substrates 70 each include the first wiring part 71P and the second wiring part 72P. The first conductive body 81 electrically connects the first conductive member 31 of each of the multiple light-emitting devices 1002 and the first wiring part 71P of each of the multiple wiring substrates 70. The second conductive body 82 electrically connects the second conductive member 32 of each of the multiple light-emitting devices 1002 and the second wiring part 72P of each of the multiple wiring substrates 70. The light-emitting module 2009 mainly differs from the light-emitting module 2005 according to the third embodiment in that multiple light-emitting devices 1002 and multiple wiring substrates 70 are included. Components included in the light-emitting module 2009 will now be described in detail. The same names and reference numerals as those of the present embodiments above indicate the same or similar members or configurations, and a detailed description is omitted as appropriate.

As shown in FIG. 23, the multiple light-emitting devices 1002 of the light-emitting module 2009 include a first light-emitting device 1000A and a second light-emitting device 1000B that are adjacent to each other. The first light-emitting device 1000A includes the light-transmitting member 50 that covers the side surface of the light source part 20 of the first light-emitting device 1000A. The second light-emitting device 1000B includes the light-transmitting member 50 that covers the side surface of the light source part of the second light-emitting device 1000B. The light-transmitting member 50 of the first light-emitting device 1000A and the light-transmitting member 50 of the second light-emitting device 1000B are separate bodies. In the specification, the light source part 20 of the first light-emitting device 1000A may be referred to as a first light source part 201, and the light source part of the second light-emitting device 1000B may be referred to as a second light source part 202.

As shown in FIG. 23, it is favorable for the surface roughness of a side surface 501 of the light-transmitting member 50 of the first light-emitting device 1000A facing the second light-emitting device 1000B to be rougher than the surface roughness of an upper surface 502 of the light-transmitting member 50 of the first light-emitting device 1000A. With this structure, it is easier to increase the surface area of the side surface 501 of the light-transmitting member 50. Accordingly, the light from the first light source part 201 is more easily extracted from the side surface 501 of the light-transmitting member 50. As a result, it is easier to inhibit the region between the first light-emitting device 1000A and the second light-emitting device 1000B from becoming excessively dark. Similarly, it is favorable for the surface roughness of a side surface 503 of the light-transmitting member 50 of the second light-emitting device 1000B facing the first light-emitting device 1000A to be rougher than the surface roughness of an upper surface 504 of the light-transmitting member 50 of the second light-emitting device 1000B. With this structure, it is easier to inhibit the region between the first light-emitting device 1000A and the second light-emitting device 1000B from becoming excessively dark. When the upper surface of the light-transmitting member 50 includes a light-transmitting hole part, the surface roughness of the upper surface 502 of the light-transmitting member 50 refers to the surface roughness of the upper surface of the light-transmitting member 50 at a portion that does not include the light-transmitting hole part. The surface roughness of each surface of the light-transmitting member 50 refers to the arithmetic average roughness Ra in accordance with JIS B 0601. The arithmetic average roughness Ra can be measured using a laser microscope, a contact-type surface roughness tester, etc.

For example, the arithmetic average roughness Ra can be measured using the laser microscope VK-X3000 (lens magnification: 50 times) manufactured by Keyence.

As shown in FIG. 23, when the first light-emitting device 1000A includes multiple light-emitting regions, it is favorable for the surface roughness of the side surface 501 of the light-transmitting member 50 of the first light-emitting device 1000A facing the second light-emitting device 1000B to be rougher than the surface roughness of one surface 505 of the light-transmitting member 50 included in the partitioning trench 50G of the first light-emitting device 1000A. With this structure, it is easier to inhibit the region between the first light-emitting device 1000A and the second light-emitting device 1000B from becoming excessively dark. Similarly, when the second light-emitting device 1000B includes multiple light-emitting regions, it is favorable for the surface roughness of the side surface 503 of the light-transmitting member 50 of the second light-emitting device 1000B facing the first light-emitting device 1000A to be rougher than the surface roughness of one surface of the light-transmitting member 50 included in the partitioning trench of the second light-emitting device 1000B.

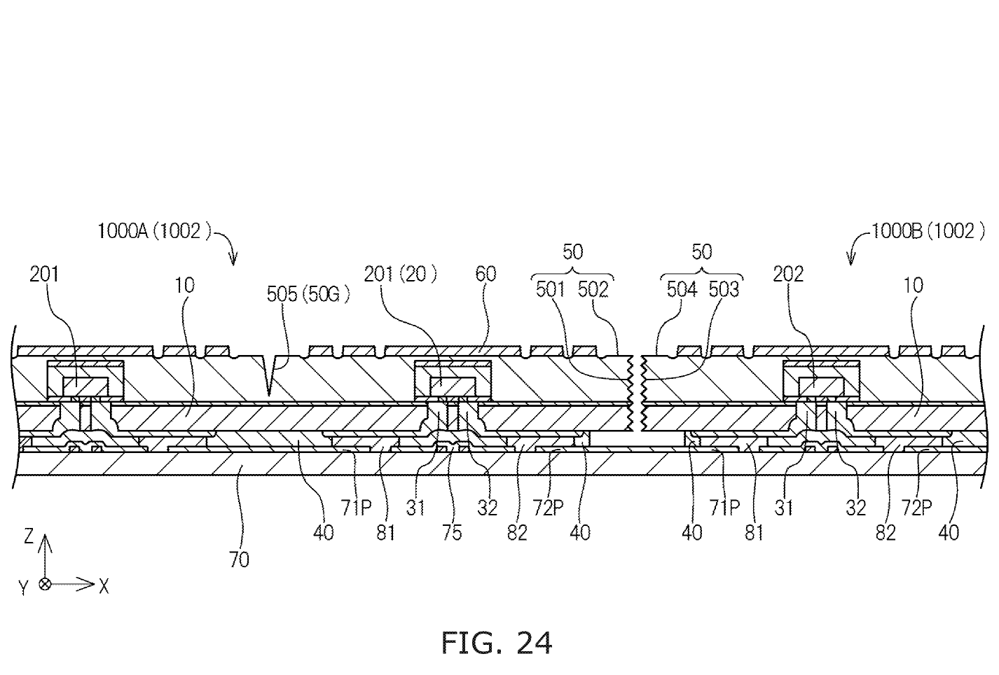

As shown in FIG. 23, the multiple wiring substrates 70 of the light-emitting module 2009 include a first wiring substrate 70A and a second wiring substrate 70B. The first wiring substrate 70A is electrically connected to the first light-emitting device 1000A. The second wiring substrate 70B is electrically connected to the second light-emitting device 1000B. The first wiring substrate 70A and the second wiring substrate 70B are adjacent to each other. It is favorable for a minimum distance L11 from the first light-emitting device 1000A to the second light-emitting device 1000B to be less than a minimum distance L12 from the first wiring substrate 70A to the second wiring substrate 70B. With this structure, it is easier to inhibit the region between the first light-emitting device 1000A and the second light-emitting device 1000B from becoming excessively dark. By increasing the minimum distance L12 from the first wiring substrate 70A to the second wiring substrate 70B, the first wiring substrate 70A and the second wiring substrate 70B are less likely to come into contact with each other, even when the positions of the first wiring substrate 70A and the second wiring substrate 70B fluctuate. Accordingly, it is easier to reduce the minimum distance L11 from the first light-emitting device 1000A to the second light-emitting device 1000B without being affected by the first wiring substrate 70A and the second wiring substrate 70B. The first light-emitting device 1000A and the second light-emitting device 1000B may be separated from each other or in contact with each other. For example, the light-transmitting member 50 of the first light-emitting device 1000A and the light-transmitting member 50 of the second light-emitting device 1000B may contact each other. As shown in FIG. 24, the first light-emitting device 1000A and the second light-emitting device 1000B may be electrically connected to one wiring substrate 70.

As shown in FIG. 23, it is favorable for a minimum distance L13 from the support body 10 of the first light-emitting device 1000A to the support body 10 of the second light-emitting device 1000B to be less than the minimum distance L12 from the first wiring substrate 70A to the second wiring substrate 70B. With this structure, it is easier to increase the area of the support body 10 of the first light-emitting device 1000A and/or the support body 10 of the second light-emitting device 1000B. Accordingly, the light from the first light source part 201 and/or the second light source part 202 is more easily reflected by the support body 10 of the first light-emitting device 1000A and/or the support body 10 of the second light-emitting device 1000B. As a result, it is easier to inhibit the region between the first light-emitting device 1000A and the second light-emitting device 1000B from becoming excessively dark. The support body 10 of the first light-emitting device 1000A and the support body 10 of the second light-emitting device 1000B may be in contact with each other or separated from each other.

As shown in FIG. 23, it is favorable for a minimum distance L14 from the light-transmitting member 50 of the first light-emitting device 1000A to the light-transmitting member 50 of the second light-emitting device 1000B to be less than the minimum distance L12 from the first wiring substrate 70A to the second wiring substrate 70B. With this structure, it is easier to reduce the region between the first light-emitting device 1000A and the second light-emitting device 1000B. As a result, it is easier to inhibit the region between the first light-emitting device 1000A and the second light-emitting device 1000B from becoming excessively dark.

As shown in FIG. 23, it is favorable for the region between the first light-emitting device 1000A and the second light-emitting device 1000B to overlap the region between the first wiring substrate 70A and the second wiring substrate 70B in the vertical direction. With this structure, the first light-emitting device 1000A and the second wiring substrate 70B are less likely to come into contact with each other, and/or the second light-emitting device 1000B and the first wiring substrate 70A are less likely to come into contact with each other. As a result, it is easier to arrange the first light-emitting device 1000A and the second light-emitting device 1000B without being affected by the first wiring substrate 70A and the second wiring substrate 70B.

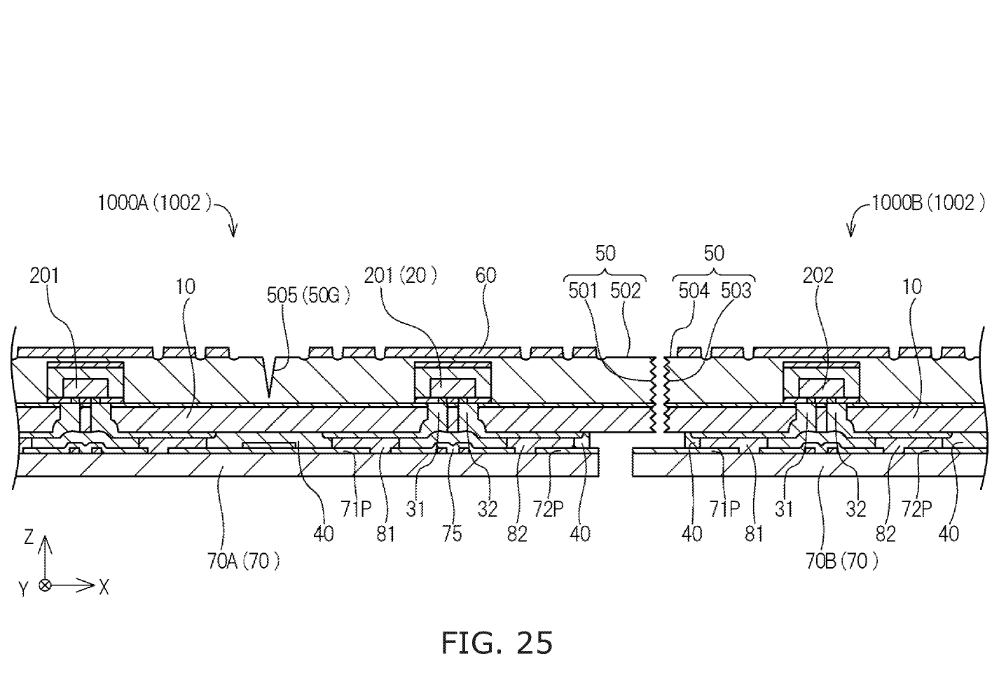

As shown in FIG. 25, the region between the first light-emitting device 1000A and the second light-emitting device 1000B may not overlap the region between the first wiring substrate 70A and the second wiring substrate 70B in the vertical direction. With this structure, the light from the first light source part 201 and/or the second light source part 202 that is extracted from the region between the first light-emitting device 1000A and the second light-emitting device 1000B is more easily reflected by the first wiring substrate 70A and/or the second wiring substrate 70B. As a result, it is easier to inhibit the region between the first light-emitting device 1000A and the second light-emitting device 1000B from becoming excessively dark.

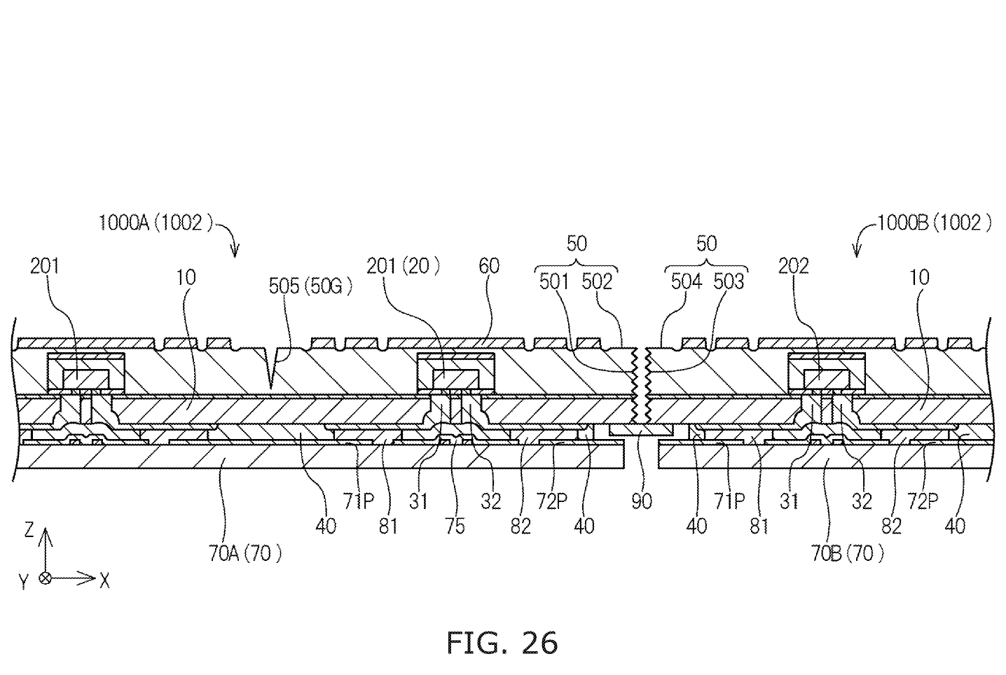

As shown in FIG. 26, the light-emitting module may include a light-reflecting member 90 that covers portions of the lower surfaces of the first and second light-emitting devices 1000A and 1000B. With this structure, the light from the first light source part 201 and/or the second light source part 202 is more easily reflected by the light-reflecting member 90. As a result, it is easier to inhibit the region between the first light-emitting device 1000A and the second light-emitting device 1000B from becoming excessively dark. It is favorable for the reflectance of the light-reflecting member 90 to the peak wavelength of the first light source part 201 and/or the second light source part 202 to be not less than 50%, and more favorably not less than 70%. It is favorable for the light-reflecting member 90 to cover portions of the upper surfaces of the first wiring substrate 70A and the second wiring substrate 70B. With this structure, it is easier to reduce the amount of the light from the first light source part 201 and/or the second light source part 202 that is absorbed by the first wiring substrate 70A and/or the second wiring substrate 70B. As a result, it is easier to inhibit the region between the first light-emitting device 1000A and the second light-emitting device 1000B from becoming excessively dark.

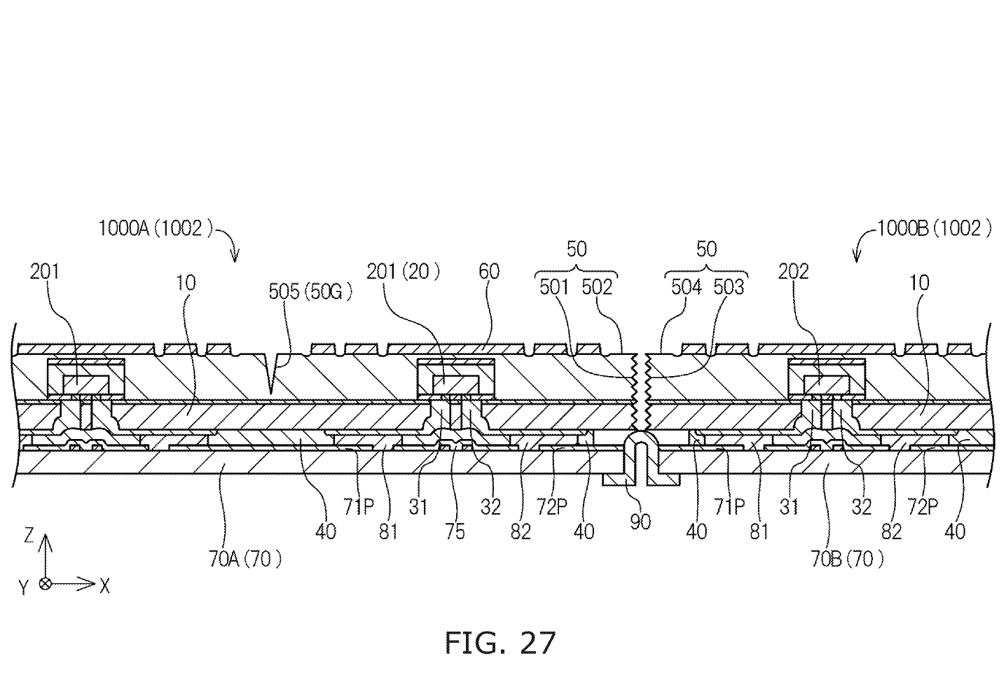

As shown in FIG. 27, the light-reflecting member 90 may cover a portion of the lower surface of the first light-emitting device 1000A with the first wiring substrate 70A disposed therebetween. Also, the light-reflecting member 90 may cover a portion of the lower surface of the second light-emitting device 1000B with the second wiring substrate 70B disposed therebetween. With this structure, the light-reflecting member 90 covers portions of the lower surfaces of the first wiring substrate 70A and/or the second wiring substrate 70B. As a result, the first wiring substrate 70A and/or the second wiring substrate 70B are more easily protected from external forces by the light-reflecting member 90. The light-reflecting member 90 may be positioned between the first wiring substrate 70A and the second wiring substrate 70B. With this structure, the light from the first light source part 201 and/or the second light source part 202 is more easily reflected by the light-reflecting member 90.

As shown in FIG. 26, the light-reflecting member 90 may not be positioned between the first light-emitting device 1000A and the second light-emitting device 1000B. With this structure, it is easier to reduce the minimum distance from the first light-emitting device 1000A to the second light-emitting device 1000B. As a result, it is easier to inhibit the region between the first light-emitting device 1000A and the second light-emitting device 1000B from becoming excessively dark. The light-reflecting member 90 may be positioned between the first light-emitting device 1000A and the second light-emitting device 1000B. With this structure, the contrast between the light-emitting region in the light-emitting state and the light-emitting region in the non-light-emitting state can be improved. For example, the contrast when the first light-emitting device 1000A is in a light-emitting state and the second light-emitting device 1000B is in a non-light-emitting state can be improved.

When the first light-emitting device 1000A includes multiple first light source parts 201 as shown in FIG. 23, it is favorable for a minimum distance L15 from the center of the first light source part 201 to the center of the second light source part 202 to be not less than 0.9 times and not more than 1.1 times a minimum distance L16 between the centers of a pair of adjacent first light source parts 201. With this structure, it is easier for the pitch between the first light source part 201 and the second light source part 202 and the pitch between the multiple first light source parts 201 to be equal. As a result, it is easier to reduce uneven luminance of the light-emitting module 2009. The minimum distance L15 from the center of the first light source part 201 to the center of the second light source part 202 may be greater or less than the minimum distance L16 between the centers of a pair of adjacent first light source parts 201. When the minimum distance L15 from the center of the first light source part 201 to the center of the second light source part 202 is less than the minimum distance L16 between the centers of the pair of adjacent first light source parts 201, it is easier to inhibit the region between the first light-emitting device 1000A and the second light-emitting device 1000B from becoming excessively dark. When the minimum distance L15 from the center of the first light source part 201 to the center of the second light source part 202 is greater than the minimum distance L16 between the centers of the pair of adjacent first light source parts 201, it is easier to inhibit the region between the first light-emitting device 1000A and the second light-emitting device 1000B from becoming excessively bright. The center of the light source part 20 refers to the geometric centroid of the light source part 20 in a top view.

Hereinabove, exemplary embodiments of the invention are described with reference to specific examples. However, the present embodiments of the invention are not limited to these specific examples. For example, additions, deletions, or modifications to some of the components or processes according to the present embodiments above also are included in the invention. The present embodiments above can be implemented in combination with each other.

Embodiments of the disclosure are useful in various illumination light sources, automotive light sources, display light sources, etc. It is especially favorable to apply embodiments of the disclosure to a backlight unit facing a liquid crystal display device.

What is claimed is:

1. A light-emitting device comprising:
a support body including:
a first surface,
a second surface opposite the first surface,
a first through-hole, and
a second through-hole;
a light source part positioned at a first surface side of the support body, the light source part comprising a first electrode and a second electrode arranged in a first direction;
a first conductive member electrically connected to the first electrode, the first conductive member comprising:
a first part positioned in the first through-hole, and
a second part positioned at a second surface side of the support body, the second part being continuous with the first part;
a second conductive member electrically connected to the second electrode, the second conductive member comprising:
a third part positioned in the second through-hole, and
a fourth part positioned at the second surface side of the support body, the fourth part being continuous with the third part; and
an insulating member overlapping at least a portion of the first part and at least a portion of the third part when viewed from the second surface side; wherein:
the first conductive member comprises:
a first region overlapping the insulating member when viewed from the second surface side, and
a second region not overlapping the insulating member when viewed from the second surface side; and
at least a portion of the second region is positioned between portions of the first region in a second direction orthogonal to the first direction.

2. The light-emitting device according to claim 1, wherein:
the second conductive member comprises:
a third region overlapping the insulating member when viewed from the second surface side, and
a fourth region not overlapping the insulating member when viewed from the second surface side; and
at least a portion of the fourth region is positioned between portions of the third region in the second direction.

3. The light-emitting device according to claim 2, wherein:
a minimum length from the second region to the fourth region is greater than a minimum length from the first part to the third part when viewed from the second surface side.

4. The light-emitting device according to claim 1, wherein:
at least a portion of the second region is positioned between the portions of the first region in the first direction.

5. The light-emitting device according to claim 1, wherein:
an entire perimeter of the second region is surrounded by the first region.

6. The light-emitting device according to claim 1, wherein:
a maximum length of the second region in the second direction is greater than a maximum length of the light source part in the second direction.

7. The light-emitting device according to claim 1, wherein:
a maximum length of the second region in the first direction is greater than a maximum length of the light source part in the first direction.

8. The light-emitting device according to claim 1, wherein:
an entirety of the light source part overlaps the insulating member when viewed from the second surface side.

9. The light-emitting device according to claim 1, wherein:
the first part comprises:
a first conductive part positioned at the first surface side, and
a second conductive part positioned at the second surface side; and
a maximum length of the second conductive part in the first direction is greater than a maximum length of the first conductive part in the first direction in a cross section including the first and second electrodes and being orthogonal to the first surface.

10. The light-emitting device according to claim 9, wherein:
an entirety of the second conductive part overlaps the insulating member when viewed from the second surface side.

11. A light-emitting module comprising:
the light-emitting device according to claim 1;
a wiring substrate comprising a first wiring part and a second wiring part;
a first conductive body electrically connecting the first conductive member and the first wiring part; and
a second conductive body electrically connecting the second conductive member and the second wiring part.

12. The light-emitting module according to claim 11, wherein:
the second conductive member comprises:
a third region overlapping the insulating member when viewed from the second surface side, and
a fourth region not overlapping the insulating member when viewed from the second surface side;
at least a portion of the fourth region is positioned between the portions of the third region in the second direction;
the first wiring part comprises a first bonding region contacting the first conductive body;
the second wiring part comprises a second bonding region contacting the second conductive body; and
a minimum distance from the first bonding region to the second bonding region is greater than a minimum length from the second region to the fourth region when viewed from the second surface side.

13. The light-emitting module according to claim 12, wherein:
the wiring substrate comprises:
a base member including a third surface facing the light-emitting device, and
a protrusion positioned at the third surface; and
at least a portion of the protrusion is positioned between the first bonding region and the second bonding region when viewed from the second surface side.

14. The light-emitting module according to claim 13, wherein:
the protrusion comprises:
at least one metal member, and
an insulating layer covering the at least one metal member.

15. The light-emitting module according to claim 14, wherein:
the at least one metal member comprises a first metal member and a second metal member arranged in the first direction; and
the first metal member and the second metal member are not electrically connected to each other.

16. The light-emitting module according to claim 14, wherein:
a maximum length of the at least one metal member in the second direction is greater than a maximum length of the second region in the second direction.

17. The light-emitting module according to claim 11, wherein:
the first part comprises:
a first conductive part positioned at the first surface side, and
a second conductive part positioned at the second surface side;
a maximum length of the second conductive part in the first direction is greater than a maximum length of the first conductive part in the first direction in a cross section that includes the first and second electrodes and is orthogonal to the first surface; and
the second conductive part does not overlap the first wiring part when viewed from the second surface side.

18. A light-emitting module comprising:
a plurality of light-emitting devices according to claim 1;
at least one wiring substrate including a first wiring part and a second wiring part;
a first conductive body electrically connecting the first conductive member of each of the plurality of light-emitting devices to the first wiring part; and
a second conductive body electrically connecting the second conductive member of each of the plurality of light-emitting devices to the second wiring part.

19. The light-emitting module according to claim 18, wherein:
the plurality of light-emitting devices include a first light-emitting device and a second light-emitting device that are adjacent to each other;
each of the first light-emitting device and the second light-emitting device comprises a light-transmitting member covering a side surface of the light source part; and
a surface roughness of a lateral surface of the light-transmitting member of the first light-emitting device facing the second light-emitting device is greater than a surface roughness of an upper surface of the light-transmitting member of the first light-emitting device.

20. The light-emitting module according to claim 18, wherein:
the plurality of light-emitting devices include a first light-emitting device and a second light-emitting device that are adjacent to each other;
the wiring substrate comprises:
a first wiring substrate electrically connected to the first light-emitting device, and
a second wiring substrate electrically connected to the second light-emitting device; and
a minimum distance from the first light-emitting device to the second light-emitting device is less than a minimum distance from the first wiring substrate to the second wiring substrate.

21. The light-emitting module according to claim 18, wherein:
the plurality of light-emitting devices include a first light-emitting device and a second light-emitting device that are adjacent to each other; and
the light-emitting module further comprises a light-reflecting member covering a portion of a lower surface of the first light-emitting device and a portion of a lower surface of the second light-emitting device.
